(19) United States
(12) Patent Application Publication
(10) Pub. No.: US 2026/0190356 A1
(43) Pub. Date: Jul. 2, 2026

(54) HIGH BANDWIDTH MEMORY AND METHOD FOR MANUFACTURING THE SAME

(71) Applicant: Samsung Electronics Co., Ltd., Suwon-si (KR)

(72) Inventors: Haseob Seong, Suwon-si (KR); DAWOON JUNG, Suwon-si (KR)

(21) Appl. No.: 19/307,851

(22) Filed: Aug. 22, 2025

(30) Foreign Application Priority Data
Dec. 27, 2024 (KR) 10-2024-0199313

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/284; H10W 90/297; H10W 90/792

(57) ABSTRACT

A high bandwidth memory may include a base die including a first surface and a second surface that is opposite to the first surface, where the first surface may include a first region and a second region around the first region, one or more dummy structures on the first region, a plurality of bump structures on the second region and next to the one or more dummy structures, and a semiconductor stack on the second surface of the base die, where the semiconductor stack may include a plurality of core dies.

### CROSS-REFERENCE TO RELATED APPLICATION

This application claims priority to and the benefit of Korean Patent Application No. 10-2024-0199313 filed with the Korean Intellectual Property Office on Dec. 27, 2024, the entire contents of which is incorporated herein by reference.

### BACKGROUND OF THE INVENTION

### (a) Field of the Invention

The present disclosure relates to a high bandwidth memory and a method for manufacturing the same.

### (b) Description of the Related Art

A semiconductor industry sector is pursuing miniaturization, weight lightening, and thinning of a semiconductor package mounted on an electronic device while simultaneously achieving higher speed, multi-function, and large capacity in response to a demand for miniaturization and weight lightening of the electronic device. Accordingly, a need for a packaging technology capable of storing more data and transmitting data at a faster speed is increasing, and the high bandwidth memory (HBM) formed by stacking a plurality of individual semiconductor chips using the packaging technology is being developed and used.

The high bandwidth memory (HBM) is manufactured by forming a memory stack in which memory dies are stacked on a base die, and has the characteristic of being able to transmit signals at a high bandwidth by using through-substrate vias (TSVs) located within the base die and within the memory dies. The height of the high bandwidth memory (HBM), the number and arrangement of through-substrate vias (TSVs), the arrangement of bump structures, IEEE 1500 specifications, PHY, and the like are defined by standard conventions such as the JEDEC standard. FIG. 1 and FIG. 2 illustrate the high bandwidth memory (HBM) 100C according to the JEDEC standard and a lower surface 120AC of the conventional base die. FIG. 1 is a cross-sectional view of the high bandwidth memory (HBM) 100C, taken along line C-C shown in FIG. 2. FIG. 2 is a top plan view (or bottom view) showing the lower surface 120AC of the base die 120.

Referring to FIG. 1 and FIG. 2, the base die 120 and the memory dies 130 include a plurality of through-substrate vias (TSVs) 123 and 133 in order to electrically connect memory dies 130 to the base die 120, and a plurality of bump structures 110 are disposed on the lower surface 120AC of the base die 120, in order to connect the base die 120 to an external processor. The lower surface 120AC of the base die 120 includes a TSV region TR in which cross-sections in a horizontal direction (X direction and Y direction) of the through-substrate vias (TSVs) 123 and 133 extending in the vertical direction (Z direction) within the base die 120 and the memory dies 130 overlap. The footprint of the through-substrate vias (TSVs) 123 and 133 included in the base die 120 and the memory dies 130 are included within the TSV region TR.

The TSV region TR is formed elongated along a first horizontal direction (X direction), and centrally located based on a second horizontal direction (Y direction). Based on the second horizontal direction (Y direction), a PHY region may be located above the TSV region TR, and a direct access (DA) region may be located below the TSV region TR. The PHY region, which is a region connected to the external processor, may be a region transmitting addresses and data. The DA region may be a region in which a logic that controls the memory dies 130 is located.

In order to test the reliability of the signal and power through-substrate vias (TSVs) 123 and 133, test pads 125 connected to the signal and power through-substrate vias (TSVs) 123 and 133 may be formed by a wiring layer of the base die 120. The test pads 125 are exposed to the outside in the center of the TSV region TR, and solder balls 112 are not disposed around an area where the test pads 125 are located. A region R defined as an empty space from the perspective of the solder ball 112 is located in a central portion of the lower surface 120AC of the base die 120 by the positions of the test pads 125 for testing the signal and power through-substrate vias (TSVs) 123 and 133, the position of the TSV region TR, or the like. The test pads 125 may be directly electrically connected to a test circuit formed in the base die 120.

As semiconductor chips become thinner due to the generational transition of semiconductor products, the frequency of cracks occurring in the base die 120 has increased, and as a result, the crack risk for high bandwidth memory (HBM) 100C has increased.

### SUMMARY OF THE INVENTION

The present disclosure attempts to provide a high bandwidth memory (HBM) capable of reducing warpage.

A high bandwidth memory may include a base die including a first surface and a second surface that is opposite to the first surface, where the first surface may include a first region and a second region around the first region, one or more dummy patterns on the first region, a plurality of bump patterns on the second region and next to the one or more dummy patterns, and a semiconductor stack on the second surface of the base die, where the semiconductor stack may include a plurality of core dies.

A high bandwidth memory may include a buffer die, where the buffer die may include a die base including a first side and a second side that is opposite to the first side, a device layer on the first side of the die base, and a wiring layer on the device layer, where the wiring layer comprises a plurality of test pads in a first region of the wiring layer and a plurality of conductive pads in a second region of the wiring layer that is positioned around the first region, one or more dummy patterns on the first region, a plurality of bump patterns on the second region, where each of the plurality of bump patterns is disposed on a corresponding conductive pad of the plurality of conductive pads, and a memory stack on the second side of the die base, where the memory stack may include a plurality of memory dies.

A high bandwidth memory may include a logic die including a first surface and a second surface that is opposite to the first surface, where the first surface may include a first region and a second region around the first region, one or more dummy patterns on the first region, a plurality of first bump patterns on the second region and next to the one or more dummy patterns, a memory stack on the second surface of the logic die, where the memory stack may include a plurality of memory dies and a plurality of interconnection layers, and the plurality of memory dies and the plurality of interconnection layers are alternately stacked, and a molding material covering the memory stack, on the second surface of the logic die.

A high bandwidth memory includes a logic die including: a first surface and a second surface facing away from the first surface, and input/output circuitry, reference voltage supply circuitry, PHY (physical layer) circuitry and direct access circuitry. The high bandwidth memory further includes: a plurality of memory dies on the second surface of the logic die; one or more dummy patterns on the first surface of the logic die; a plurality of bump patterns on the first surface of the logic die and directly electrically connected to the input/output circuitry and/or the reference voltage supply circuitry; a plurality of PHY solder balls on the first surface of the logic die and directly electrically connected to the PHY circuitry; and a plurality of direct access pads on the first surface of the logic die and directly electrically connected to the direct access circuitry. The one or more dummy patterns are electrically isolated from circuitry located external to the high bandwidth memory, and the plurality of direct access pads, the plurality of PHY solder balls and the plurality of bump patterns are configured to be directly electrically connected to the circuitry located external to the high bandwidth memory.

A manufacturing method of a high bandwidth memory may include providing a buffer die in which a plurality of test pads are formed in a first region of the wiring layer and a plurality of conductive pads are formed in a second region around the first region of the wiring layer, forming at least one dummy pattern on the first region, forming a plurality of bump patterns on the second region, where each of the plurality of bump patterns is formed on a corresponding conductive pad of the plurality of conductive pads, and forming a memory stack on the buffer die.

A semiconductor package comprises a package substrate including an upper surface having a plurality of substrate pads; and a high bandwidth memory formed on the package substrate. The high bandwidth memory includes a base die and a stack of memory dies on an upper surface of the base die. The base die has a bottom surface having a plurality of first die pads and a plurality of first conductive pillars, each of the plurality of first conductive pillars formed on a corresponding one of the plurality of first die pads, and a plurality of second die pads and a plurality of second conductive pillars, each of the plurality of second conductive pillars formed on a corresponding one of the plurality of second die pads. Each of the plurality of first conductive pillars is directly electrically connected to a corresponding one of the plurality of substrate pads, and each of the plurality of second conductive pillars vertically overlap the package substrate and is electrically isolated from the package substrate.

A manufacturing method comprises forming a HBM (high bandwidth memory) including providing a logic die having input/output circuitry, reference voltage supply circuitry, PHY (physical layer) circuitry, direct access circuitry, and a first surface and a second surface facing away from the first surface, the first surface of the logic die including test pads and first pads. The forming of the HBM further includes forming a plurality of memory dies on the second surface of the logic die. The manufacturing method further comprises testing the HBM by including electrically connecting test probes to the test pads of the logic die to provide testing signals to circuits of the logic die; after testing the HBM, forming dummy patterns on corresponding ones of the test pads of the logic die and forming die bumps on the first pads of the logic die; and attaching the HBM to a package substrate including connecting the die bumps to corresponding substrate pads of the package substrate. Each of the dummy patterns vertically overlap the package substrate and is electrically isolated from the package substrate.

By disposing a dummy pattern in a region where solder balls are not disposed below the base die of the high bandwidth memory (HBM), the uniformity of material may be improved (e.g., a metal ratio on the lower surface of the base die may be uniformly set). Accordingly, this can reduce warpage of the high bandwidth memory (HBM), prevent cracks occurring in the region where solder balls are not disposed below the base die due to stress concentration caused by the warpage, and as a result, prevent cracks from propagating to the wiring layer or device layer of the base die.

### BRIEF DESCRIPTION OF THE DRAWINGS

FIG. 1 is a cross-sectional view showing a conventional high bandwidth memory.

FIG. 2 is a top plan view showing a lower surface of a conventional base die.

FIG. 3 is a top plan view showing a lower surface of a base die of an embodiment.

FIG. 4 is a cross-sectional view showing a high bandwidth memory of an embodiment.

FIG. 5 is a drawing showing an enlarged view of the region E of FIG. 3 and the region F of FIG. 4 according to an embodiment.

FIG. 6 is a drawing showing an enlarged view of the region E of FIG. 3 and the region F of FIG. 4 according to an embodiment.

FIG. 7 is a drawing showing an enlarged view of the region E of FIG. 3 and the region F of FIG. 4 according to an embodiment.

FIG. 8 is a drawing showing an enlarged view of the region E of FIG. 3 and the region F of FIG. 4 according to an embodiment.

FIG. 9 is a drawing showing an enlarged view of the region E of FIG. 3 and the region F of FIG. 4 according to an embodiment.

FIG. 10 is a drawing showing an enlarged view of the region E of FIG. 3 and the region F of FIG. 4 according to an embodiment.

FIG. 11 is a drawing showing an enlarged view of the region E of FIG. 3 and the region F of FIG. 4 according to an embodiment.

FIG. 12 is a drawing showing an enlarged view of the region E of FIG. 3 and the region F of FIG. 4 according to an embodiment.

FIG. 13 is a drawing showing an enlarged view of the region E of FIG. 3 and the region F of FIG. 4 according to an embodiment.

FIG. 14 to FIG. 27 are cross-sectional views for explaining a method of forming a dummy structure on a base die of the high bandwidth memory of the embodiment of FIG. 4.

FIG. 28 to FIG. 31 are cross-sectional views for explaining a method of forming the high bandwidth memory of the embodiment of FIG. 4.

FIG. 32 is a cross-sectional view showing a high bandwidth memory of an embodiment.

FIG. 33 to FIG. 36 are cross-sectional views for explaining a method of forming the high bandwidth memory of the embodiment of FIG. 32.

FIG. 37 is a cross-sectional view showing a high bandwidth memory of an embodiment.

FIG. 38 to FIG. 41 are cross-sectional views for explaining a method of forming the high bandwidth memory of the embodiment of FIG. 37.

FIG. 42 is a cross-sectional view illustrating an exemplary product that utilizes an interposer according to an embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Further, in the drawings, the size and thickness of each element may be arbitrarily illustrated for ease of description, and the present invention is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In contrast, when an element is referred to as being “directly connected” or “directly coupled” to another element, or as “contacting” or “in contact with” another element (or using any form of the word “contact”), there are no intervening elements present at the point of contact.

In addition, unless explicitly described to the contrary, the word “comprise” and variations such as “comprises” or “comprising” will be understood to imply the inclusion of stated elements but not the exclusion of any other elements. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present (at least at the point of contact).

Further, in the specification, the word “on” may mean positioned above the object portion, and does not necessarily mean positioned on the upper side of the object portion based on a gravitational direction.

Further, throughout the specification, the phrase “in a plan view” means viewing a target portion from the top, and the phrase “in a cross sectional view” (or in a cross-section) means viewing a vertical cross-section of a target portion from the side, unless context indicates otherwise. For example, items described as being viewed as a horizontal cross-section describe a cross-section of a target portion viewed from a top-down view.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes. Components described as “actively electrically connected” refers to components that are electrically connected through at least one active element that is in an “on” state to allow electrical signals to pass therethrough.

Hereinafter, a high bandwidth memory (HBM) 100A according to an embodiment and a manufacturing method of the high bandwidth memory (HBM) 100A will be described with reference to the drawings.

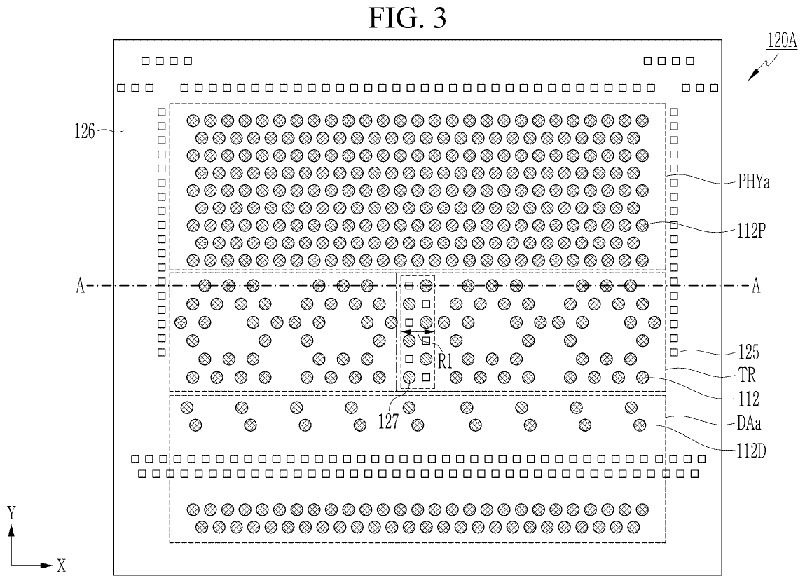

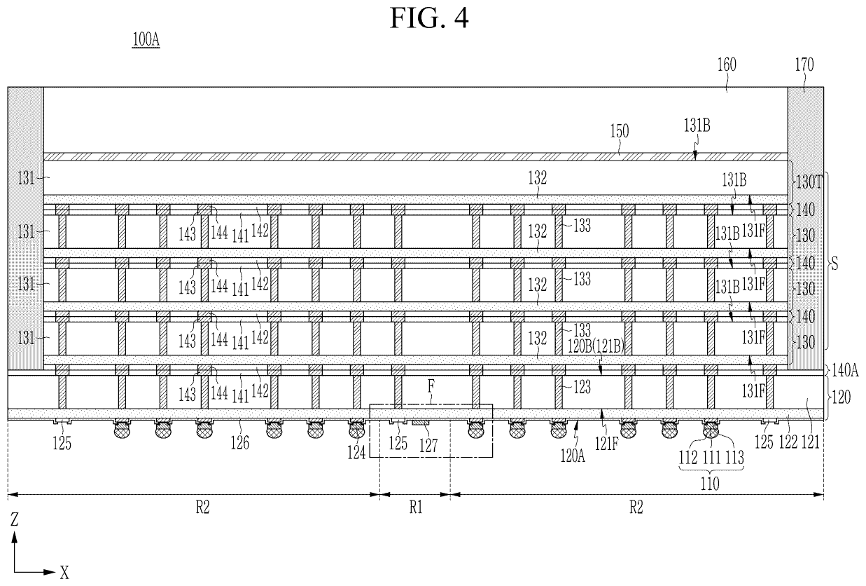

FIG. 3 is a top plan view (or bottom view) showing a lower surface (i.e., first surface) 120A of a base die 120 of the high bandwidth memory (HBM) 100A of the embodiment of FIG. 4.

Referring to FIG. 3, the high bandwidth memory (HBM) 100A may include bump structures (or conductive bump patterns or die bumps) 110 disposed on a lower surface 120A of the base die 120, test pads 125 exposed from the lower surface 120A of the base die 120, and one or more dummy structures (or dummy patterns or dummy bumps) 127 disposed on the base die 120. FIG. 4 illustrates solder balls 112 of the bump structures 110. The bump patterns 110 may form terminals of the high bandwidth memory to directly electrically connect to a device or circuitry located) external to the high bandwidth memory. The dummy structures 127 may be electrically isolated from all circuits formed within the base die 120. The dummy patterns 127 may be configured to be electrically isolated from the circuitry located external to the high bandwidth memory. The test pads 125 also may be configured to be electrically isolated from the circuitry located external to the high bandwidth memory, and the external circuitry does not include circuits in a test equipment. In a plan view, the test pads 125 may be spaced apar from the solder balls 112 of the bump structures 110. The test pads may be configured to be electrically connected to pins of a probe card to provide testing signals to circuits of the base die 120 in a test process.

The lower surface 120A of the base die 120 may include a TSV region TR, in which cross-sections in a horizontal direction (X direction and Y direction) of first through-substrate vias (TSVs) 123 extending in a vertical direction (Z direction; see FIG. 4) within the base die 120 overlap, and cross-sections in the horizontal direction (X direction and Y direction) of second through-substrate vias (TSVs) 123 extending in the vertical direction (Z direction; see FIG. 4) within each of memory dies 130 overlap. The footprint of the first through-substrate vias (TSVs) 123 and the footprint of the second through-substrate vias (TSVs) 123 may be included within the TSV region TR. For example, the through-substrate vias (TSVs) 123 and 133 are disposed in the TSV region TR. The TSVs 123 and 133 extend in the vertical direction (Z direction) through the base die 120 and/or the memory dies 130. Each of the TSVs 123 and 133 in one of the base die 120 and the memory dies 130 is vertically aligned with a corresponding set of the TSVs in other of the base die 120 and the memory dies 130.

The TSV region TR may be formed elongated along a first horizontal direction (X direction), and may be centrally located based on a second horizontal direction (Y direction). Based on the second horizontal direction (Y direction), a PHY (physical layer) region PHYa may be located above the TSV region TR in a plan view, and a direct access (DA) region DAa may be located below the TSV region TR in a plan view. The PHY region, which is a region connected to the external processor, may be a region transmitting addresses and data. The DA region may be a region in which a logic that controls the memory dies 130 is located. For example, in a plan view, the TSV region TR may be disposed between the PHY region PHYa and the DA region DAa, and the solder balls 112 may be disposed between PHY solder balls 112P and DA solder balls 112D. The solder balls 112 may be directly electrically connected to input/output circuitry and/or reference voltage supply circuitry of the base die. The base die 120 may have PHY circuitry for transmitting addresses and data, and the PHY solder balls 112P may be directly electrically connected to the PHY circuitry for transmitting addresses and data. The PHY solder balls 112P may be directly electrically connected to the external processor. The base die 120 may have logic circuitry (or DA circuitry) for control of the memory dies 130, and the DA solder balls 112D may be directly electrically connected to the logic circuitry. In a plan view, the plurality of DA solder balls 112D, the plurality of PHY solder balls 112P and the plurality of bump patterns 110 surround the one or more dummy patterns 127.

In the TSV region TR, the lower surface 120A of the base die 120 may include a first region R1 where the bump structures 110 is not disposed, and a second region R2 other than the first region R1. Since the first region R1 is centrally located on the lower surface 120A of the base die 120, the second region R2 may surround the first region R1.

The bump structures 110 may be disposed in order to connect the high bandwidth memory (HBM) 100A to an external processor. The bump structures 110 may be directly electrically connected to the circuitry located external to the high bandwidth memory. The bump structures 110 located within the TSV region TR may be electrically connected to the first through-substrate vias (TSVs) 123 extending in the vertical direction (Z direction; see FIG. 4) within (or penetrating through) the base die 120 and the second through-substrate vias (TSVs) 133 extending in the vertical direction (Z direction; see FIG. 4) within (or penetrating through) a corresponding one of the memory dies 130. The bump structures 110 are not disposed within the first region R1. The first region R1 may be defined as an empty space from the perspective of a solder ball 112.

The test pads 125 may be formed by a wiring layer of the base die 120, and may be exposed to the outside on the lower surface 120A of the base die 120. In an embodiment, the test pads 125 may include or be an electrical die sorting (EDS) test pad. The first region R1 may not include the bump structures 110, and include the test pads 125. The test pads 125 located within the first region R1 may be directly electrically connected to the first through-substrate vias (TSVs) 123 and the second through-substrate vias (TSVs) 123 in order to test the reliability of the first through-substrate vias (TSVs) 123 and the second through-substrate vias (TSVs) 123.

The one or more dummy structures 127 may be disposed on the lower surface 120A of the base die 120. The one or more dummy structures 127 may have no electrical function, and may be electrically separated (or isolated) from other components. The one or more dummy structures 127 may be electrically isolated from conductive pads 124 and other portions of the wiring layer. The one or more dummy structures 127 may be located within the first region R1. The first region R1 may not include the bump structures 110, and include the one or more dummy structures 127. By disposing the one or more dummy structures 127 in the first region R1 where the bump structures 110 are not disposed on the lower surface 120A of the base die 120 of the high bandwidth memory (HBM) 100A, the uniformity of material may be improved (e.g., the metal ratio on the lower surface 120A of the base die 120 may be adjusted to be uniform). Accordingly, this can reduce warpage of the high bandwidth memory (HBM) 100A, prevent cracks occurring by stress concentration due to the warpage, and as a result, prevent cracks from propagating to the wiring layer or a device layer of the base die 120.

FIG. 4 is a cross-sectional view showing the high bandwidth memory (HBM) 100A of an embodiment. FIG. 4 is a cross-sectional view of the high bandwidth memory (HBM) 100A taken along line A-A in the embodiment of FIG. 3.

Referring to FIG. 4, the high bandwidth memory (HBM) 100A may include the bump structures 110, a base die (i.e., a logic die or a buffer die) 120, the one or more dummy structures 127, a first interconnection structure (or first interconnection layer) 140A, memory stack (i.e., semiconductor stack) S, an adhesive member 150, a dummy die 160, and a molding material 170. The high bandwidth memory (HBM) 100A is a high-performance, three-dimensional (3D) stacked dynamic random-access memory (DRAM). The high bandwidth memory (HBM) 100A may have memory channels through a memory stack S manufactured by vertically stacking memory dies 130 to simultaneously implement shorter latency and higher bandwidth compared with a conventional DRAM product, and may reduce a total area occupied by individual DRAMs on a substrate so that it is advantageous for high bandwidth per area and reduces power consumption.

The bump structures 110 may be disposed between the base die 120 and an external device. Each of the bump structures 110 may be disposed on each of the conductive pads 124 of the base die 120, and may directly electrically connect the conductive pads 124 of the base die 120 to an external device. Each of the bump structures 110 may include a bump pillar 111 and a solder ball 112. In an embodiment, the bump structures 110 may include or be micro-bumps. The bump pillar 111 may be disposed between a corresponding conductive pad 124 of the conductive pad 124 and the solder ball 112. For example, the dummy patterns 127 and the bump pillar 111 may be formed of the same material. The conductive pads 124 may be directly electrically connected to the circuitry located external to the high bandwidth memory. The dummy patterns 127 may be additional bump pillars each of which does not have a corresponding solder ball formed thereon. The dummy pattern itself may not be used for testing or may be configured to connect to an external device.

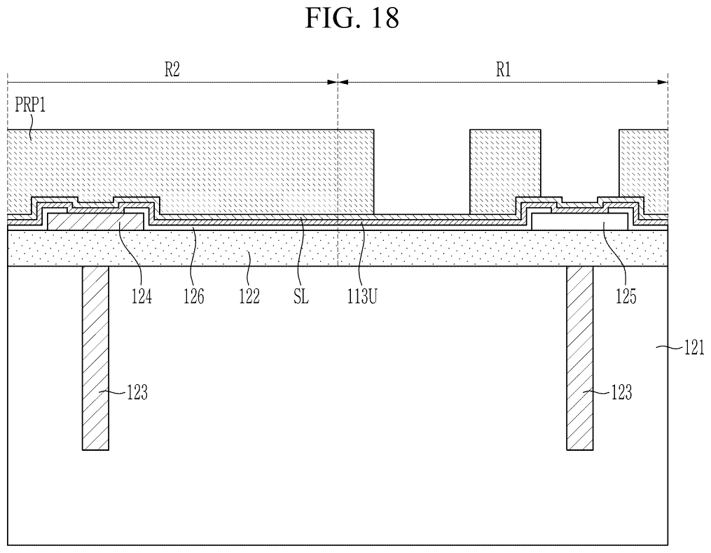

An under bump metallurgy (UBM) layer 113 may be interposed between the bump pillar 111 and the conductive pad 124. The under bump metallurgy (UBM) layer 113 may include a diffusion barrier wall layer 113U (see FIG. 18) and a seed metal layer SL (see FIG. 18). The diffusion barrier wall layer 113U and the seed metal layer SL may line a space between the bump pillar 111 and the conductive pad 124, and between the bump pillar 111 and a protection layer 126. The diffusion barrier wall layer 113U may improve electric characteristics between the bump pillar 111 and the conductive pad 124. The diffusion barrier wall layer 113U may serve as an adhesion layer. The seed metal layer SL may not be distinguishable from the bump pillar 111.

The base die 120 may be disposed between the memory stack S and an external device. The base die 120 may be a buffer die. When data are exchanged between devices with different data processing speeds, processing units, and usage times, data loss may occur due to a difference in the data processing speeds, the processing units, and the usage times between the devices. To prevent the loss, the base die 120 may be disposed between the memory dies 130 and the external device so that information when data are exchanged between the memory dies 130 and the external device may be temporarily stored in the base die 120. When data are transmitted to or received from the memory dies 130, the base die 120 may sequentially pass the data after arranging an order of the data.

The base die 120 may include a die base 121, a front side structure 122, the first through-substrate vias (TSVs) 123, the conductive pads 124, the test pads 125, and the protection layer 126. The base die 120 may include a first surface 120A and a second surface 120B that is opposite to the first surface 120A. For example, the first surface 120A and the second surface 120B may face away from each other. The die base 121 may be disposed such that its front side faces the bump structures 110. The die base 121 may be a die formed from a wafer. In an embodiment, the die base 121 may include silicon or another semiconductor material.

The front side structure 122 may be disposed between the die base 121 and the bump structures 110. The front side structure 122 may include an active layer and a wiring layer. The active layer may correspond to a front side of the die base 121. The active layer may form transistors that may be interconnected to form an integrated circuit of the base die 120. In an embodiment, integrated circuit may include at least one of an active device and a passive device. In an embodiment, integrated circuit may include transistors having a gate, a channel region and source/drain regions. In an embodiment, integrated circuit may include transistors, diodes, capacitors, inductors, resistors, etc. The wiring layer may be disposed on the active layer. The wiring layer may include signal wire lines, power wire lines, contact plugs, and inter-metal dielectric (IMD). The first region R1 defined by dividing the lower surface 120A of the base die 120 and the second region R2 around the first region R1 may be equally applied to the wiring layer.

The first through-substrate vias (TSVs) 123 (such as through-silicon vias) may be disposed within the die base 121. Each of the first through-substrate vias (TSVs) 123 may be disposed between the wiring layer of the front side structure 122 and each of first bonding pads 143 of the first interconnection structure 140A on a back side 121B of the die base 121. Each of the first through-substrate vias (TSVs) 123 may directly electrically connect the wiring layer of the front side structure 122 to a corresponding first bonding pad 143 of the first bonding pads 143 of the first interconnection structure 140A on the back side 121B of the die base 121. The first through-substrate vias (TSVs) 123 may include first signal through-substrate vias and first power through-substrate vias. In an embodiment, the first through-substrate vias (TSVs) 123 may include at least one of tungsten, aluminum, copper, and an alloy thereof.

The conductive pads 124 may be disposed within the wiring layer, or on the wiring layer. The conductive pads 124 may be located within the second region R2. Each of the conductive pads 124 may be directly electrically connected to a corresponding bump structure 110 of the bump structures 110.

The test pads 125 may be formed by the wiring layer, or on the wiring layer. The test pads 125 may be located within the first region R1. Each of the test pads may be directly electrically connected to a corresponding first signal through-substrate via of the first signal through-substrate vias or a corresponding first power through-substrate via of a plurality of first power through-substrate vias. The test pads 125 may be exposed to the outside. The test pads 125 may include probe marks. For example, each of the plurality of test pads 125 may be directly electrically connected to a corresponding one of either the plurality of signal through-substrate vias or the plurality of power through-substrate vias. A recess may be formed on a surface of each of the test pads 125. For example, the test pads 125 may include probe marks, which result from mechanical contact to pins of a probe card for testing the HBM.

The protection layer 126 may be disposed on the wiring layer. The protection layer 126 may cover a part of upper surfaces and a side surface of the conductive pads 124. The protection layer 126 may not cover a remaining portion of upper surfaces of the conductive pads 124. Through the uncovered remaining portion of the upper surfaces of the conductive pads 124, the conductive pad 124 may be in contact with and directly electrically connected to the bump pillar 111. The protection layer 126 may include an organic dielectric. In an embodiment, the protection layer 126 may include photoimageable dielectrics (PID). In an embodiment, photoimageable dielectrics (PID) may include a polyimide-based photoactive polymer, a novolac-based photoactive polymer, polybenzoxazole, a silicone-based polymer, an acrylate-based polymer, or an epoxy-based polymer.

The one or more dummy structures 127 may be disposed on the wiring layer. The one or more dummy structures 127 may be disposed next to the bump structures 110. The one or more dummy structures 127 may be disposed on at least one of the protection layer 126 and the test pads 125. The one or more dummy structures 127 may be located within the first region R1. The one or more dummy structures 127 may be electrically separated (or isolated) from the base die 120. In an embodiment, the one or more dummy structures 127 may include at least one of metal, silicon, and epoxy.

The first interconnection structure 140A may be disposed between the back side 121B of the die base 121 and the memory stack S. The first interconnection structure 140A may include a back side insulating layer 141 on the back side 121B of the die base 121, a front side insulating layer 142 on a front side structure 132 of the memory die 130, back side bonding pads 143 on the back side 121B of the die base 121, and front side bonding pads 144 on the front side structure 132 of the memory die 130. The back side insulating layer 141 may be directly bonded to the front side insulating layer 142. The back side insulating layer 141 may surround and insulate the back side bonding pads 143. The front side insulating layer 142 may surround and insulate the front side bonding pads 144. In an embodiment, the back side insulating layer 141 and the front side insulating layer 142 may include at least one of silicon oxide and silicon nitride. In an embodiment, the back side insulating layer 141 and the front side insulating layer 142 may include SiO₂, SiN, or SiCN.

The back side bonding pads 143 may be disposed to penetrate the back side insulating layer 141. Levels of bonding surfaces of the back side bonding pads 143 may be the same as a level of a bonding surface of the back side insulating layer 141. Side surfaces of the back side bonding pads 143 may be surrounded by the back side insulating layer 141. Each of the back side bonding pads 143 may be directly electrically connected to a corresponding first through-substrate via 123 of the first through-substrate vias (TSVs) 123. Each of the back side bonding pads 143 may be directly bonded to a corresponding front side bonding pad 144 of the front side bonding pads 144. The front side bonding pads 144 may be disposed to penetrate the front side insulating layer 142. Levels of bonding surfaces of the front side bonding pads 144 may be the same as a level of a bonding surface of the front side insulating layer 142. Side surfaces of the front side bonding pads 144 may be surrounded by the front side insulating layer 142. Each of the front side bonding pads 144 may be directly electrically connected to a corresponding wire of wires of the front side structure 132 of the memory die 130. By directly bonding between the back side bonding pads 143 and the front side bonding pads 144, electrical connection can be made between the base die 120 and the memory stack S. In an embodiment, the back side bonding pads 143 and the front side bonding pads 144 may include copper or a conductive material capable of applying hybrid bonding.

The memory stack S may be disposed on the second surface 120B (the back side 121B of the die base 121) of the base die 120. The memory stack S may include the memory dies 130 stacked in the vertical direction and second interconnection structures (or second interconnection layers) 140 alternating with the memory dies 130. Although FIG. 4 illustrates the memory stack S including four memory dies 130, it is not limited thereto, and the memory stack S including more or fewer number of memory dies 130 may be included within the scope of the present disclosure. For example, the memory stack S may include four, eight, twelve, sixteen, or twenty memory dies 130.

A memory die (i.e., semiconductor die or core die) 130 may include a memory die base 131, the front side structure 132, and the second through-substrate vias (TSVs) 133. A memory die 130T located uppermost in the memory stack S may not include the second through-substrate vias (TSVs) 133. In an embodiment, the memory die 130 may include or be a DRAM.

The memory die base 131 may be disposed such that a front side 131F of the memory die base 131 faces the bump structures 110. The memory die base 131 may be a die formed from a wafer. In an embodiment, the memory die base 131 may include silicon or another semiconductor material.

The front side structure 132 may be disposed on the front side 131F of the memory die base 131. The front side structure 132 may include an active layer and a wiring layer. The active layer may be disposed on a front side of the memory die base 131. The active layer may include an integrated circuit structure having integrated circuit regions. In an embodiment, integrated circuit structure may include at least one of an active device and a passive device. In an embodiment, integrated circuit structure may include a gate structure, a source region, and a drain region. In an embodiment, integrated circuit structure may include at least one of a transistor, a diode, a capacitor, an inductor, and a resistor. The wiring layer may be disposed on the active layer. The wiring layer may include signal wire lines, power wire lines, contact plugs, and inter-metal dielectric (IMD).

The second through-substrate vias (TSVs) 133 may be disposed within the memory die base 131. Each of the second through-substrate vias (TSVs) 133 may be disposed between the wiring layer of the front side structure 132 and each of the first bonding pads 143 of the second interconnection structure 140 on a back side 131B of the memory die base 131. Each of the second through-substrate vias (TSVs) 133 may directly electrically connect the wiring layer of the front side structure 132 to the corresponding first bonding pad 143 of the first bonding pads 143 of the second interconnection structure 140 on the back side 131B of the memory die base 131. The second through-substrate vias (TSVs) 133 may include second signal through-substrate vias and second power through-substrate vias. In an embodiment, the second through-substrate vias (TSVs) 133 may include at least one of tungsten, aluminum, copper, and an alloy thereof.

The second interconnection structures 140 may be alternately stacked on the memory dies 130. Each of the second interconnection structures 140 may be disposed between the back side 131B of the memory die base 131 of the memory die 130 and the front side structure 132 of a neighboring memory die 130. Each of the second interconnection structures 140 may include a first insulating layer (i.e., back side insulating layer) 141 on the back side 121B of the memory die base 131, a second insulating layer (i.e., front side insulating layer) 142 on the front side structure 132 of the memory die 130, first bonding pads (i.e., back side bonding pads) 143 on the back side 131B of the memory die base 131, and second bonding pads (i.e., front side bonding pads) 144 on the front side structure 132 of the memory die 130. A first insulating layer 141 may be directly bonded to a second insulating layer 142. The first insulating layer 141 may surround and insulate the first bonding pads 143. The second insulating layer 142 may surround and insulate second bonding pads 144. In an embodiment, the first insulating layer 141 and the second insulating layer 142 may include at least one of silicon oxide and silicon nitride. In an embodiment, the first insulating layer 141 and the second insulating layer 142 may include SiO₂, SiN, or SiCN.

The first bonding pads 143 may be disposed to penetrate the first insulating layer 141. Levels of bonding surfaces of the first bonding pads 143 may be the same as a level of a bonding surface of the first insulating layer 141. Side surfaces of the first bonding pads 143 may be surrounded by the first insulating layer 141. Each of the first bonding pads 143 may be directly electrically connected to a corresponding second through-substrate via 133 of the second through-substrate vias (TSVs) 133. Each of the first bonding pads 143 may be directly bonded to a corresponding second bonding pad 144 of the second bonding pads 144. The second bonding pads 144 may be disposed to penetrate the second insulating layer 142. Levels of bonding surfaces of the second bonding pads 144 may be the same as a level of a bonding surface of the second insulating layer 142. Side surfaces of the second bonding pads 144 may be surrounded by the second insulating layer 142. Each of the second bonding pads 144 may be directly electrically connected to a corresponding wire of wires of the memory die 130. By directly bonding between the first bonding pads 143 and the second bonding pads 144, electrical connection can be made between the memory dies 130. In an embodiment, the first bonding pads 143 and the second bonding pads 144 may include copper or a conductive material capable of applying hybrid bonding.

The adhesive member 150 may be disposed between the memory stack S and the dummy die 160. The adhesive member 150 may attach the dummy die 160 to the memory die 130T located in an uppermost portion of the memory stack S. In an embodiment, the adhesive member 150 may include a thermal interface material (TIM). The thermal interface material (TIM) may be inserted between the memory stack S and the dummy die 160, to improve thermal coupling between the memory stack S and the dummy die 160. The thermal interface material (TIM) may fill an air layer of a contacting surface between the memory stack S and the dummy die 160 to serve to reduce the thermal contact resistance.

The dummy die (i.e., dummy structure) 160 may be disposed on the memory stack S. The dummy die 160 may be attached to the memory stack S by the adhesive member 150. The dummy die 160 may be thermally connected to the memory stack S. In an embodiment, the dummy die 160 may include or be a heat dissipation structure. In an embodiment, the heat dissipation structure may include a heat slug, a heat sink, or a heat spreader. In an embodiment, the heat dissipation structure may include a conductive material having high thermal conductivity. In an embodiment, the dummy die 160 may include at least one of copper, aluminum, silver, tin, gold, nickel, lead, titanium, and an alloy thereof.

The molding material 170 may cover the memory stack S, the adhesive member 150, and the dummy die 160, on the second surface 120B of the base die 120. An upper surface of the dummy die 160 may be exposed from the molding material 170, and may have the same level as a level of an upper surface of the molding material 170.

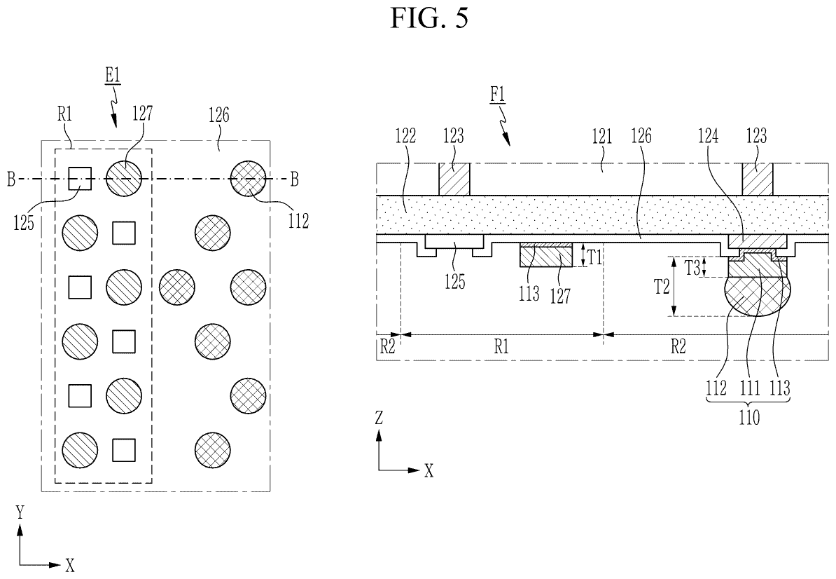

FIG. 5 is a drawing showing an enlarged view of the region E of FIG. 3 and the region F of FIG. 4 according to an embodiment. A region F1 of FIG. 5 is a cross-sectional view taken along line B-B from a region E1 of FIG. 5.

Referring to the region E1 of FIG. 5, a plurality of dummy structures 127 may be disposed on the protection layer 126, within the first region R1. The plurality of dummy structures 127 may be arranged in one or more rows. The plurality of dummy structures 127 may be disposed in a staggered manner with respect to each other. The plurality of dummy structures 127 may be disposed to be spaced apart from the test pads 125. The plurality of dummy structures 127 may not overlap with the test pads 125 in the vertical direction (Z direction). A footprint of the plurality of dummy structures 127 may not overlap with a footprint of the test pads 125. Although it is illustrated that, in the region E1 of FIG. 5, each of the plurality of dummy structures 127 has a circular planar shape, it is not limited thereto, and in an embodiment, each of the plurality of dummy structures 127 may have a planar shape of a circular shape, an elliptical shape, an elongated line shape, a rectangular shape, or a polygonal shape.

Referring to the region F1 of FIG. 5, each of the plurality of dummy structures 127 may be disposed on the protection layer 126, within the first region R1. Each of the plurality of dummy structures 127 may have a first thickness T1 in the vertical direction (Z direction). The bump structure 110 may include the bump pillar 111 and the solder ball 112. The bump structure 110 may have a second thickness T2 in the vertical direction (Z direction). The first thickness T1 may be smaller than the second thickness T2. The bump pillar 111 may have a third thickness T3 in the vertical direction (Z direction). The third thickness T3 may be equal to the first thickness T1, or greater than the first thickness T1. A thickness of the under bump metallurgy (UBM) layer 113 on the dummy structure 127 and on the bump pillar 111 may be ignored because it is significantly smaller compared to a thickness of the dummy structure 127, and compared to a thickness of the bump pillar 111.

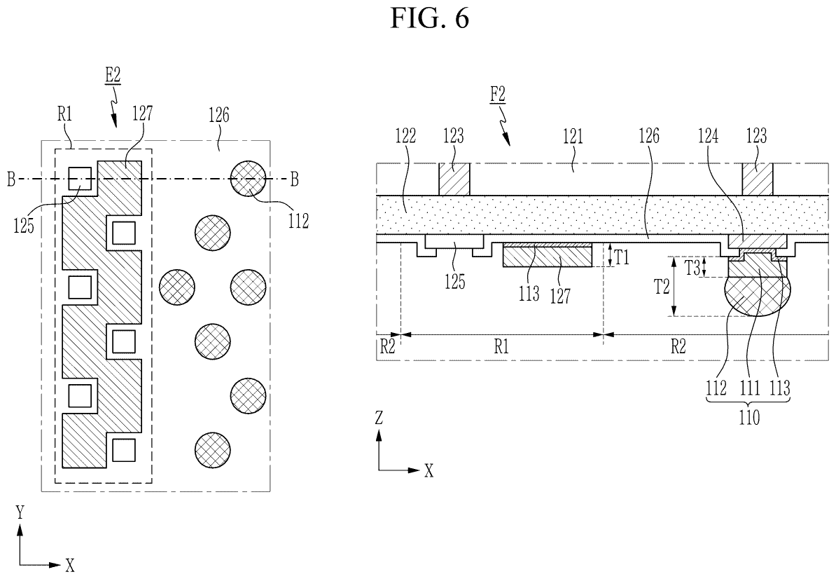

FIG. 6 is a drawing showing an enlarged view of the region E of FIG. 3 and the region F of FIG. 4 according to an embodiment. A region F2 of FIG. 6 is a cross-sectional view taken along line B-B from a region E2 of FIG. 6.

Referring to the region E2 of FIG. 6, a single dummy structure 127 may be disposed on the protection layer 126, within the first region R1. The single dummy structure 127 may fill at least a portion of the first region R1 excluding the test pads 125. The single dummy structure 127 may be disposed around the test pads 125. The single dummy structure 127 may conformally extend along a side surface of the test pads 125. The single dummy structure 127 may have an integral structure. The single dummy structure 127 may alternately extend along the first horizontal direction (X direction) and along the second horizontal direction (Y direction). The single dummy structure 127 may be disposed to be spaced apart from the test pads 125. The single dummy structure 127 may not overlap with the test pads 125 in the vertical direction (Z direction). A footprint of the single dummy structure 127 may not overlap with the footprint of the test pads 125. Although it is illustrated that, in the region E2 of FIG. 6, the single dummy structure 127 has a planar shape in which rectangles continuously extend, it is not limited thereto, and in an embodiment, the single dummy structure 127 may have a planar shape in which circular shapes, elliptical shapes, elongated line shapes, rectangular shapes, or polygonal shapes continuously extend.

Referring to the region F2 of FIG. 6, the dummy structure 127 may be disposed on the protection layer 126, within the first region R1. The dummy structure 127 may have the first thickness T1 in the vertical direction (Z direction). The bump structure 110 may include the bump pillar 111 and the solder ball 112. The bump structure 110 may have the second thickness T2 in the vertical direction (Z direction). The first thickness T1 may be smaller than the second thickness T2. The bump pillar 111 may have the third thickness T3 in the vertical direction (Z direction). The third thickness T3 may be equal to the first thickness T1, or greater than the first thickness T1.

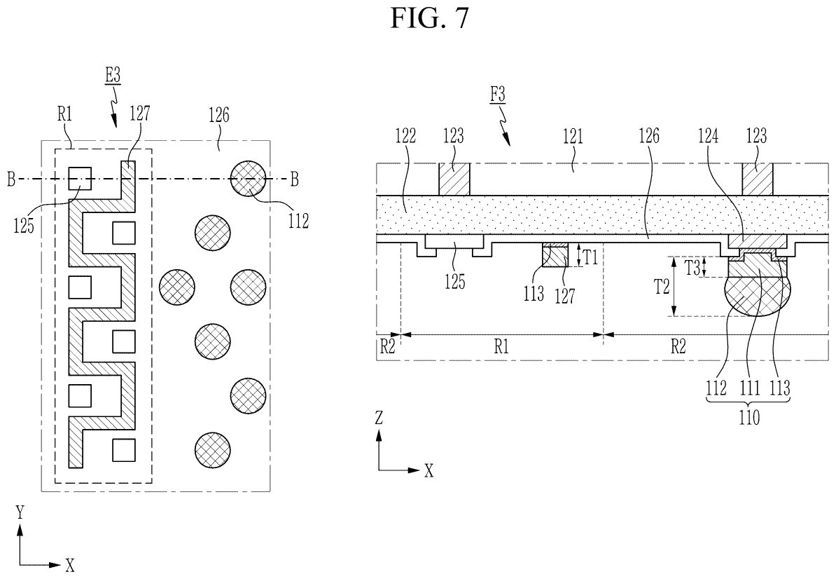

FIG. 7 is a drawing showing an enlarged view of the region E of FIG. 3 and the region F of FIG. 4 according to an embodiment. A region F3 of FIG. 7 is a cross-sectional view taken along line B-B from a region E3 of FIG. 7.

Referring to the region E3 of FIG. 7, the single dummy structure 127 in an elongated shape may be disposed on the protection layer 126 within the first region R1. The single dummy structure 127 may be disposed around the test pads 125. The single dummy structure 127 may conformally extend along the side surface of the test pads 125. The single dummy structure 127 may have an integral structure. The single dummy structure 127 may alternately extend along the first horizontal direction (X direction) and along the second horizontal direction (Y direction). The single dummy structure 127 may be disposed to be spaced apart from the test pads 125. The single dummy structure 127 may not overlap with the test pads 125 in the vertical direction (Z direction). The footprint of the single dummy structure 127 may not overlap with the footprint of the test pads 125. Although it is illustrated that, in the region E3 of FIG. 7, the single dummy structure 127 has a planar shape in which elongated shapes continuously extend, it is not limited thereto, and in an embodiment, the single dummy structure 127 may have a planar shape in which circular shapes, elliptical shapes, elongated line shapes, rectangular shapes, or polygonal shapes continuously extend. In addition, the plurality of dummy structures 127 having a shape arranged side by side and continuously extending, other than the single dummy structure 127, may be included in the scope of the present disclosure.

Referring to the region F3 of FIG. 7, the dummy structure 127 may be disposed on the protection layer 126, within the first region R1. The dummy structure 127 may have the first thickness T1 in the vertical direction (Z direction). The bump structure 110 may include the bump pillar 111 and the solder ball 112. The bump structure 110 may have the second thickness T2 in the vertical direction (Z direction). The first thickness T1 may be smaller than the second thickness T2. The bump pillar 111 may have the third thickness T3 in the vertical direction (Z direction). The third thickness T3 may be equal to the first thickness T1, or greater than the first thickness T1.

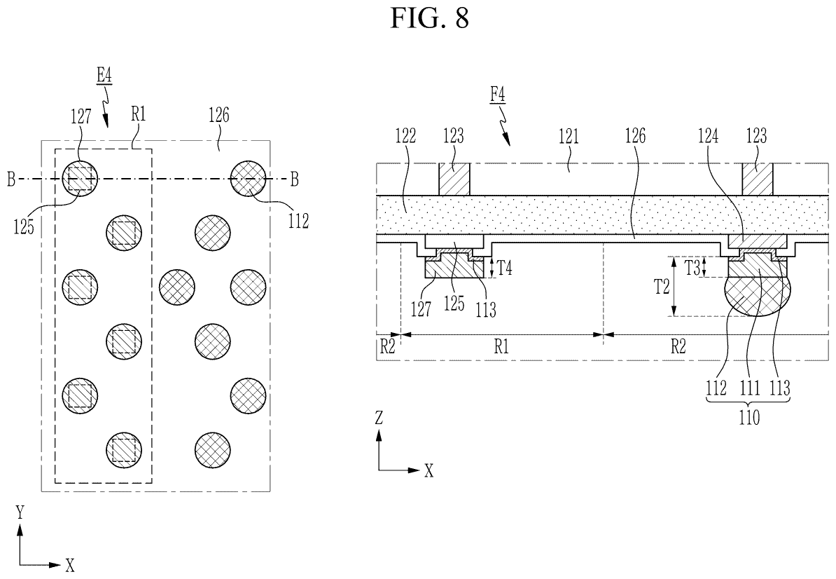

FIG. 8 is a drawing showing an enlarged view of the region E of FIG. 3 and the region F of FIG. 4 according to an embodiment. A region F4 of FIG. 8 is a cross-sectional view taken along line B-B from a region E4 of FIG. 8.

Referring to the region E4 of FIG. 8, the plurality of dummy structures (dummy bumps) 127 may be disposed within the first region R1. Each of the plurality of dummy structures 127 may be disposed on a corresponding test pad 125 of the test pads 125. The plurality of dummy structures 127 may be consecutively arranged in one or more rows. The plurality of dummy structures 127 may be disposed in a staggered manner. Each of the plurality of dummy structures 127 may be disposed to contact the test pads 125. The plurality of dummy structures 127 may overlap with the test pads 125 in the vertical direction (Z direction). The test pads 125 may be directly electrically connected to a corresponding one of the plurality of dummy structures 127. The footprint of the plurality of dummy structures 127 may overlap with the footprint of the test pads 125. Although it is illustrated that, in the region E4 of FIG. 8, each of the plurality of dummy structures 127 has a circular planar shape, it is not limited thereto, and in an embodiment, each of the plurality of dummy structures 127 may have a planar shape of a circular shape, an elliptical shape, an elongated shape, a rectangular line shape, or a polygonal shape.

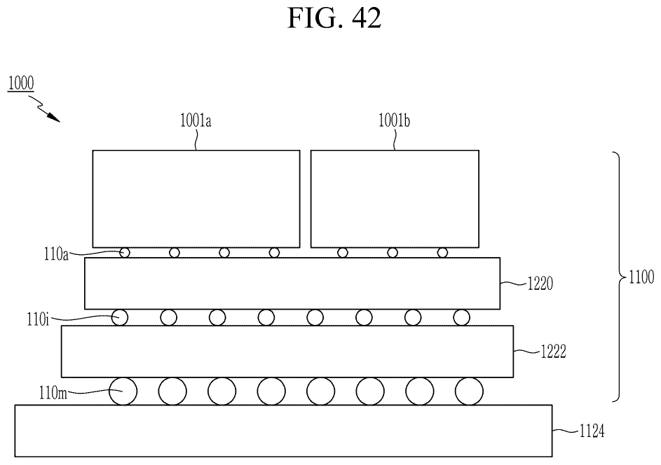

Referring to the region F4 of FIG. 8, each of the plurality of dummy structures 127 may be disposed on a corresponding test pad 125 of the test pads 125 within the first region R1. Each of the plurality of dummy structures 127 may be a dummy pillar. Each of the plurality of dummy structures 127, which is a dummy pillar, may be free of solder balls. Each of the plurality of dummy structures 127 may have a fourth thickness T4 in the vertical direction (Z direction). The bump structure (die bump)110 may include the bump pillar 111 and the solder ball 112. The bump structure 110 may have the second thickness T2 in the vertical direction (Z direction). Fourth thickness T1 may be smaller than the second thickness T2. The bump pillar 111 may have the third thickness T3 in the vertical direction (Z direction). The fourth thickness T4 may be equal to the third thickness T3. The die bumps 110 may terminate in the vertical direction (Z direction) at a first vertical level at the upper surface of the package substrate (the bottom of the die bumps may be at a first vertical level). The dummy bumps 127 may terminate in the vertical direction at a second vertical level higher than the first vertical level to be spaced apart from the upper surface of the first package substrate 1220 which will be described with reference to FIG. 42.

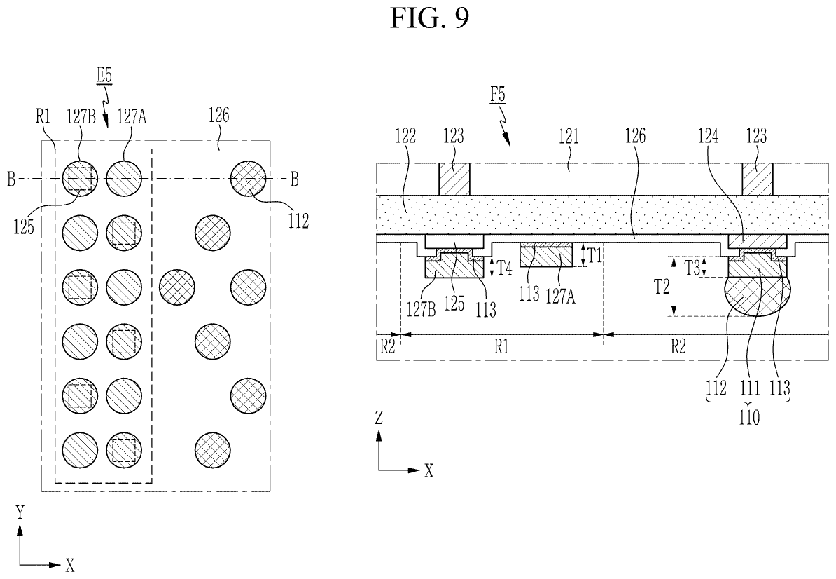

FIG. 9 is a drawing showing an enlarged view of the region E of FIG. 3 and the region F of FIG. 4 according to an embodiment. A region F5 of FIG. 9 is a cross-sectional view taken along line B-B from a region E5 of FIG. 9.

Referring to the region E5 of FIG. 9, the plurality of dummy structures 127 may be disposed within the first region R1. The plurality of dummy structures 127 may be arranged in one or more rows. The plurality of dummy structures 127 may include dummy structures 127A that are not disposed on the test pads 125 and dummy structures 127B that are disposed on the test pads 125. The dummy structures 127A that are not disposed on the test pads 125 may not overlap with the test pads 125 in the vertical direction (Z direction). The dummy structures 127A that are not disposed on the test pads 125 may be disposed in a staggered manner with respect to each other. The dummy structures 127B that are disposed on the test pad 125 may be disposed in a staggered manner with respect to each other. Each of the dummy structures 127B that are disposed on the test pad 125 may be disposed to contact a corresponding test pad 125 of the test pads 125. The dummy structures 127B that are disposed on the test pad 125 may overlap with the test pads 125 in the vertical direction (Z direction). Footprints of the dummy structures 127B that are disposed on the test pad 125 may overlap with the footprint of the test pads 125. Although it is illustrated that, in the region E5 of FIG. 9, each of the plurality of dummy structures 127 has a circular planar shape, it is not limited thereto, and in an embodiment, each of the plurality of dummy structures 127 may have a planar shape of a circular shape, an elliptical shape, an elongated line shape, a rectangular shape, or a polygonal shape.

Referring to the region F5 of FIG. 9, each of the dummy structures 127A that are not disposed on the test pads 125 may be disposed on the protection layer 126. Each of the dummy structures 127A that are not disposed on the test pads 125 may have the first thickness T1 in the vertical direction (Z direction). The bump structure 110 may include the bump pillar 111 and the solder ball 112. The bump structure 110 may have the second thickness T2 in the vertical direction (Z direction). The first thickness T1 may be smaller than the second thickness T2. The bump pillar 111 may have the third thickness T3 in the vertical direction (Z direction). The third thickness T3 may be equal to the first thickness T1, or greater than the first thickness T1.

Each of the dummy structures 127B that are disposed on the test pad 125 may be disposed on a corresponding test pad 125 of the test pads 125 within the first region R1. Each of the dummy structures 127B that are disposed on the test pad 125 may be a dummy pillar. Each of the dummy structures 127B, which is a dummy pillar, may be free of solder balls. Each of the dummy structures 127B that are disposed on the test pad 125 may have the fourth thickness T4 in the vertical direction (Z direction). The fourth thickness T4 may be smaller than the second thickness T2. The fourth thickness T4 may be equal to the third thickness T3.

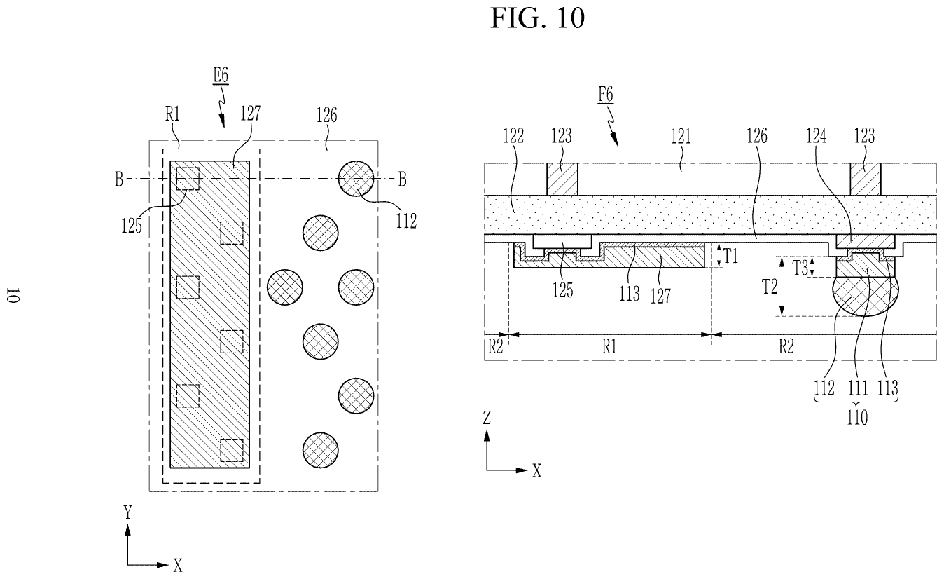

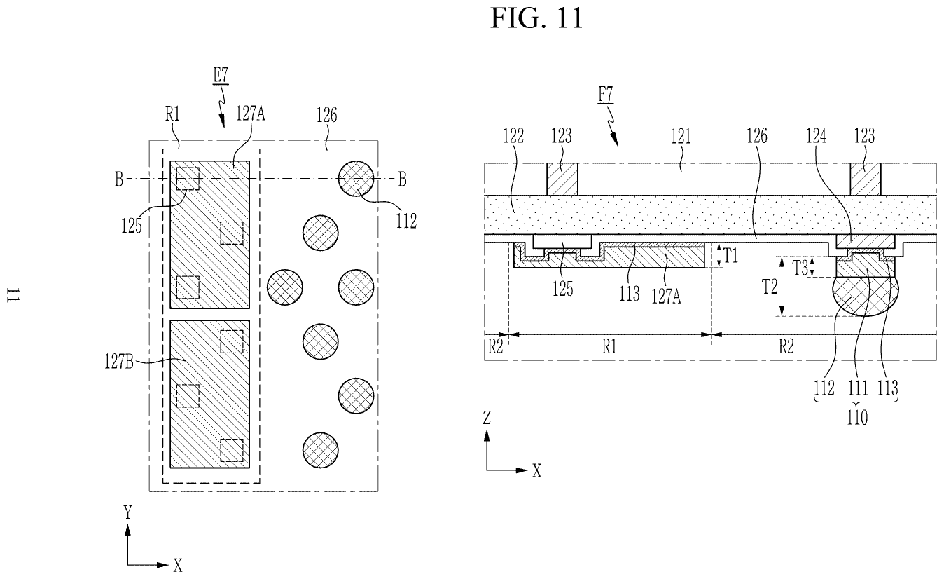

FIG. 10 is a drawing showing an enlarged view of the region E of FIG. 3 and the region F of FIG. 4 according to an embodiment. A region F6 of FIG. 10 is a cross-sectional view taken along line B-B from a region E6 of FIG. 11.

Referring to the region E6 of FIG. 10, the single dummy structure 127 may cover at least a portion of the first region R1 including the test pads 125. The single dummy structure 127 may be disposed to contact the test pads 125. The single dummy structure 127 may overlap with the test pads 125 in the vertical direction (Z direction). The footprint of the single dummy structure 127 may overlap with the footprint of the test pads 125. Although it is illustrated that, in the region E6 of FIG. 10, the single dummy structure 127 has a rectangular planar shape, it is not limited thereto, and in an embodiment, the single dummy structure 127 may have a planar shape of a circular shape, an elliptical shape, a rectangular shape, or a polygonal shape.

Referring to the region F6 of FIG. 10, the dummy structure 127 may be disposed on the protection layer 126 and on the test pads 125, within the first region R1. The dummy structure 127 may have a first maximum thickness T1 in the vertical direction (Z direction). The bump structure 110 may include the bump pillar 111 and the solder ball 112. The bump structure 110 may have the second thickness T2 in the vertical direction (Z direction). The first maximum thickness T1 may be smaller than the second thickness T2. The bump pillar 111 may have the third thickness T3 in the vertical direction (Z direction). The third thickness T3 may be equal to the first maximum thickness T1, or greater than the first maximum thickness T1.

FIG. 11 is a drawing showing an enlarged view of the region E of FIG. 3 and the region F of FIG. 4 according to an embodiment. A region F7 of FIG. 11 is a cross-sectional view taken along line B-B from a region E7 of FIG. 11.

Referring to the region E7 of FIG. 11, the plurality of dummy structures 127 may cover at least a portion of the first region R1 including the test pads 125. The plurality of dummy structures 127 may be disposed to contact the test pads 125. The plurality of dummy structures 127 may overlap with the test pads 125 in the vertical direction (Z direction). The footprint of the plurality of dummy structures 127 may overlap with the footprint of the test pads 125. Although it is illustrated that, in the region E7 of FIG. 11, each of the plurality of dummy structures 127 has a rectangular planar shape, it is not limited thereto, and in an embodiment, each of the plurality of dummy structures 127 may have a planar shape of a circular shape, an elliptical shape, a rectangular shape, or a polygonal shape.

Referring to the region F7 of FIG. 11, the dummy structure 127 may be disposed on the protection layer 126 and on the test pads 125, within the first region R1. The dummy structure 127 may have the first maximum thickness T1 in the vertical direction (Z direction). The bump structure 110 may include the bump pillar 111 and the solder ball 112. The bump structure 110 may have the second thickness T2 in the vertical direction (Z direction). The first maximum thickness T1 may be smaller than the second thickness T2. The bump pillar 111 may have the third thickness T3 in the vertical direction (Z direction). The third thickness T3 may be equal to the first maximum thickness T1, or greater than the first maximum thickness T1.

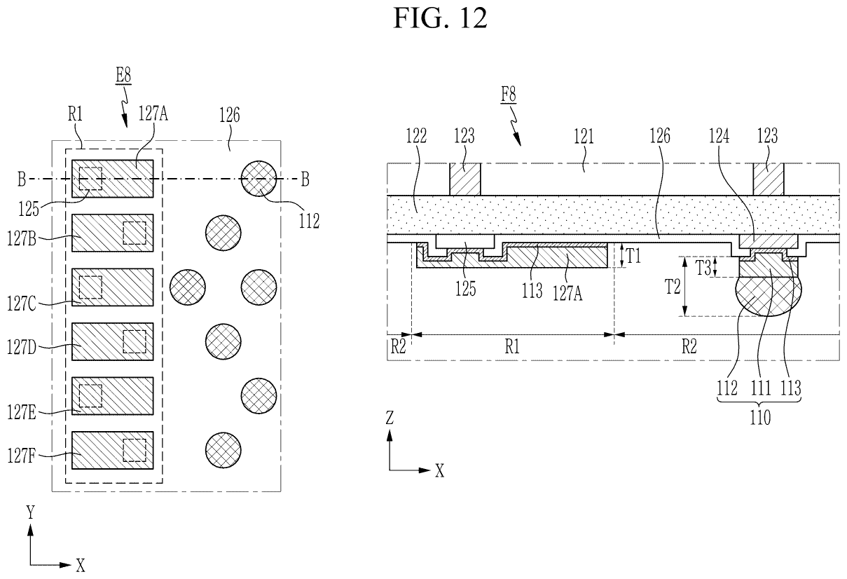

FIG. 12 is a drawing showing an enlarged view of the region E of FIG. 3 and the region F of FIG. 4 according to an embodiment. A region F8 of FIG. 12 is a cross-sectional view taken along line B-B from a region E8 of FIG. 12.

Referring to the region E8 of FIG. 12, the plurality of dummy structures 127 may cover at least a portion of the first region R1 including the test pads 125. The plurality of dummy structures 127 may be disposed to contact the test pads 125. The plurality of dummy structures 127 may be disposed to extend in the first horizontal direction (X direction). The plurality of dummy structures 127 may overlap with the test pads 125 in the vertical direction (Z direction). The footprint of the plurality of dummy structures 127 may overlap with the footprint of the test pads 125. Although it is illustrated that, in the region E8 of FIG. 12, each of the plurality of dummy structures 127 has a rectangular planar shape, it is not limited thereto, and in an embodiment, each of the plurality of dummy structures 127 may have a planar shape of a circular shape, an elliptical shape, a rectangular shape, or a polygonal shape.

Referring to the region F8 of FIG. 12, the dummy structure 127 may be disposed on the protection layer 126 and on the test pads 125, within the first region R1. The dummy structure 127 may have the first maximum thickness T1 in the vertical direction (Z direction). The bump structure 110 may include the bump pillar 111 and the solder ball 112. The bump structure 110 may have the second thickness T2 in the vertical direction (Z direction). The first maximum thickness T1 may be smaller than the second thickness T2. The bump pillar 111 may have the third thickness T3 in the vertical direction (Z direction). The third thickness T3 may be equal to the first maximum thickness T1, or greater than the first maximum thickness T1.

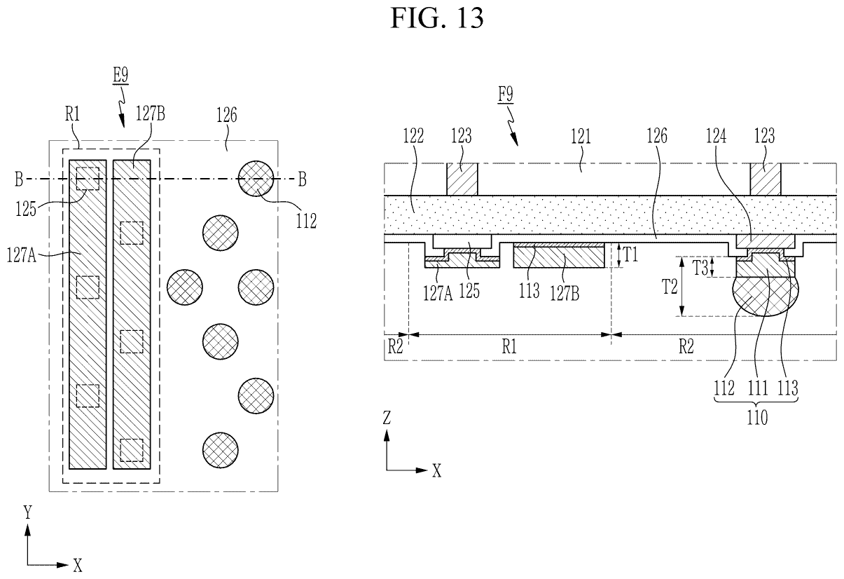

FIG. 13 is a drawing showing an enlarged view of the region E of FIG. 3 and the region F of FIG. 4 according to an embodiment. A region F9 of FIG. 13 is a cross-sectional view taken along line B-B from a region E9 of FIG. 13.

Referring to the region E9 of FIG. 13, the plurality of dummy structures 127 may cover at least a portion of the first region R1 including the test pads 125. The plurality of dummy structures 127 may be arranged in one or more rows. The plurality of dummy structures 127 may be disposed to contact the test pads 125. The plurality of dummy structures 127 may be disposed to extend in the second horizontal direction (Y direction). The plurality of dummy structures 127 may overlap with at least one test pad 125 of the test pads 125 in the vertical direction (Z direction). The footprint of the plurality of dummy structures 127 may overlap with the footprint of the test pads 125. Although it is illustrated that, in the region E9 of FIG. 13, each of the plurality of dummy structures 127 has a planar shape of a rectangular elongated shape, it is not limited thereto, and in an embodiment, each of the plurality of dummy structures 127 may have a planar shape of an elliptical shape, an elongated line shape, or a polygonal elongated shape.

Referring to the region F9 of FIG. 13, each of the plurality of dummy structures 127 may be disposed on the protection layer 126 and on the test pads 125, within the first region R1. Each of the plurality of dummy structures 127 may have the first maximum thickness T1 in the vertical direction (Z direction). The bump structure 110 may include the bump pillar 111 and the solder ball 112. The bump structure 110 may have the second thickness T2 in the vertical direction (Z direction). The first maximum thickness T1 may be smaller than the second thickness T2. The bump pillar 111 may have the third thickness T3 in the vertical direction (Z direction). The third thickness T3 may be equal to the first maximum thickness T1, or greater than the first maximum thickness T1.

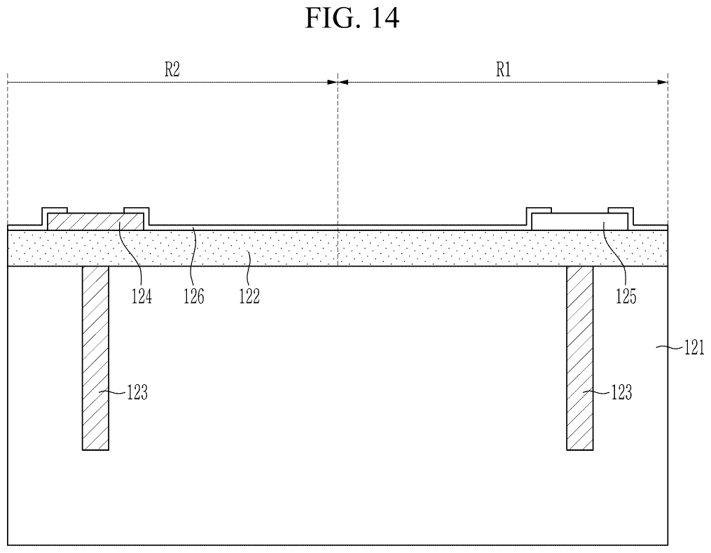

FIG. 14 to FIG. 27 are cross-sectional views for explaining a method of forming the dummy structure 127 on the base die 120 of the high bandwidth memory (HBM) 100A of the embodiment of FIG. 4.

FIG. 14 is a cross-sectional view that illustrates providing the die base 121 of the base die 120.

Referring to FIG. 14, the base die 120 may be provided where the first through-substrate vias (TSVs) 123 may be formed within the die base 121, the test pads 125 may be formed in the first region R1 of the wiring layer of the front side structure 122 of the base die 120, and the conductive pads 124 are formed in the second region R2 of the wiring layer.

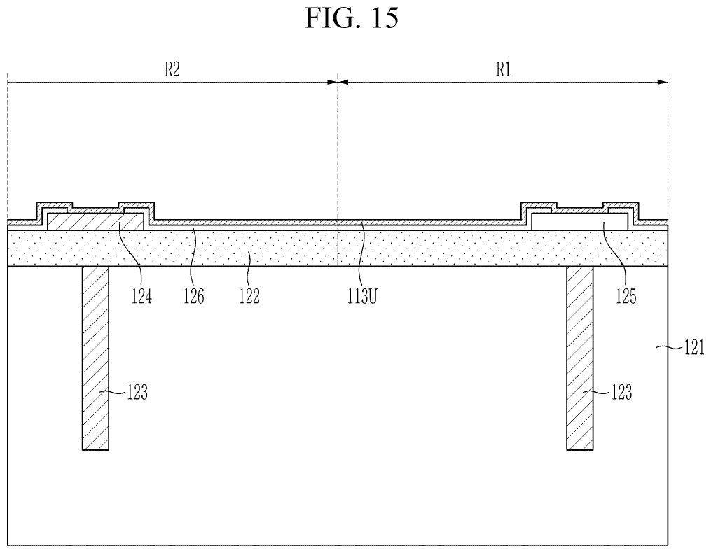

FIG. 15 is a cross-sectional view that illustrates forming the diffusion barrier wall layer 113U of the under bump metallurgy (UBM) layer 113.

Referring to FIG. 15, the diffusion barrier wall layer 113U may be formed continuously and conformally, along the protection layer 126 of the base die 120, along the surfaces of the conductive pads 124 exposed from the protection layer 126, and along surfaces of the test pads 125 exposed from the protection layer 126. In an embodiment, the diffusion barrier wall layer 113U may be formed by performing a sputtering process. In an embodiment, the diffusion barrier wall layer may include at least one of tantalum nitride, titanium nitride, tantalum, titanium, and an alloy thereof. In an embodiment, the diffusion barrier wall layer may have a thickness in a range of about 50 nm to about 500 nm.

In some embodiments, before forming the bump metallurgy (UBM) layer 113 (or before forming the dummy structures 127), a test process may be performed using a probe card. The test may induce a recess on the test pad 125 resulting from mechanical contact to a pin of the probe card.

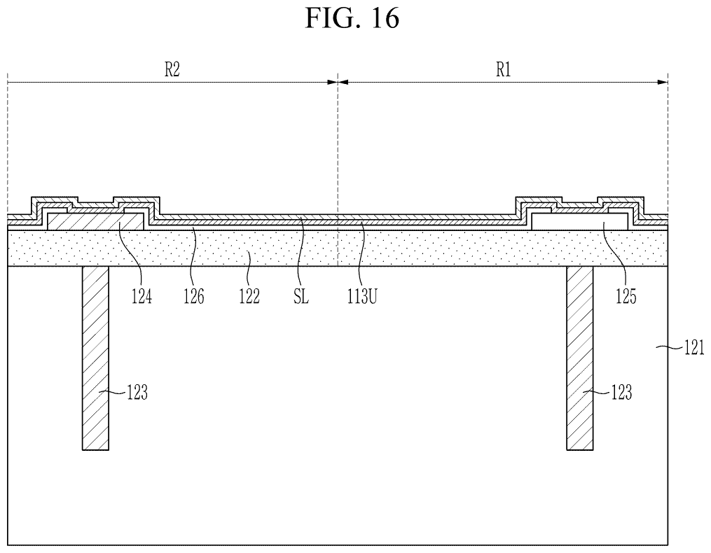

FIG. 16 is a cross-sectional view that illustrates forming the seed metal layer SL on the diffusion barrier wall layer 113U.

Referring to FIG. 16, the seed metal layer SL may be formed on the diffusion barrier wall layer 113U. The seed metal layer SL may be formed continuously and conformally along the diffusion barrier wall layer 113U. In an embodiment, the seed metal layer SL may be formed by performing a sputtering process or electroless plating process. In an embodiment, the seed metal layer may have a thickness in a range of about 200 nm to about 800 nm. In an embodiment, the seed metal layer may be formed of a copper alloy including silver, chromium, nickel, tin, gold, and a combination thereof, or copper.

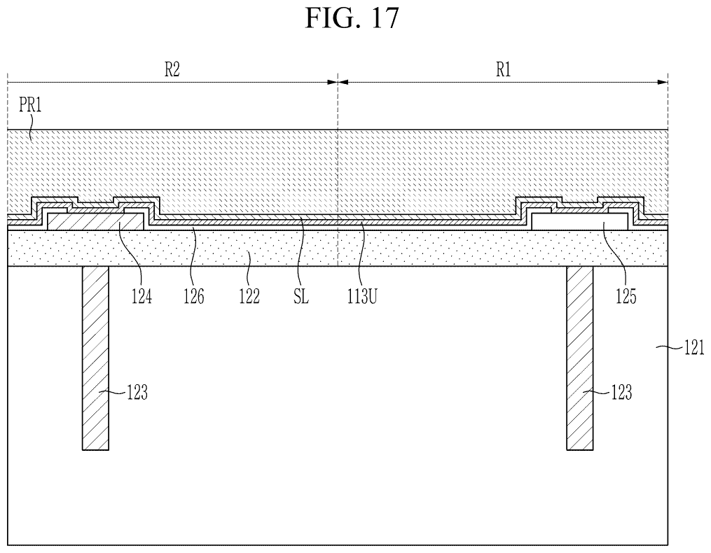

FIG. 17 is a cross-sectional view that illustrates forming a first photoresist PR1 on the seed metal layer SL.

Referring to FIG. 17, the first photoresist PR1 may be applied on the seed metal layer SL. In an embodiment, the first photoresist PR1 may be formed through a spin coating process. In an embodiment, the first photoresist PR1 may include an organic polymer resin including a photosensitivity material.

FIG. 18 is a cross-sectional view that illustrates forming a first photoresist pattern PRP1.

Referring to FIG. 18, by exposing and developing the first photoresist PR1, the first photoresist pattern PRP1 may be formed. The seed metal layer SL may be exposed through the first photoresist pattern PRP1.

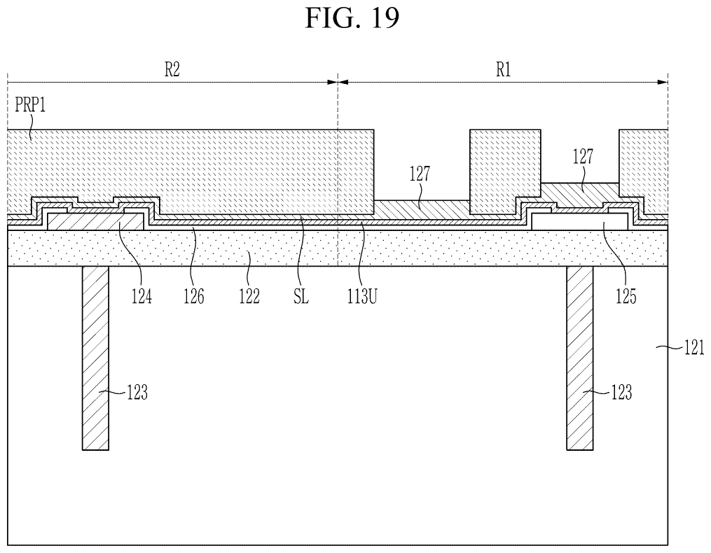

FIG. 19 is a cross-sectional view that illustrates forming the one or more dummy structures 127.

Referring to FIG. 19, by growing a metal layer through electrolytic plating from the seed metal layer SL that is already formed, the one or more dummy structures 127 may be formed. The one or more dummy structures 127 may be formed within the first region R1. The dummy structure 127, which is a dummy pillar, may be formed on the test pad 125. The seed metal layer SL may not be distinguishable from the one or more dummy structures 127. In an embodiment, the dummy structure 127 may be formed of a copper alloy including silver, chromium, nickel, tin, gold, and a combination thereof, or copper.

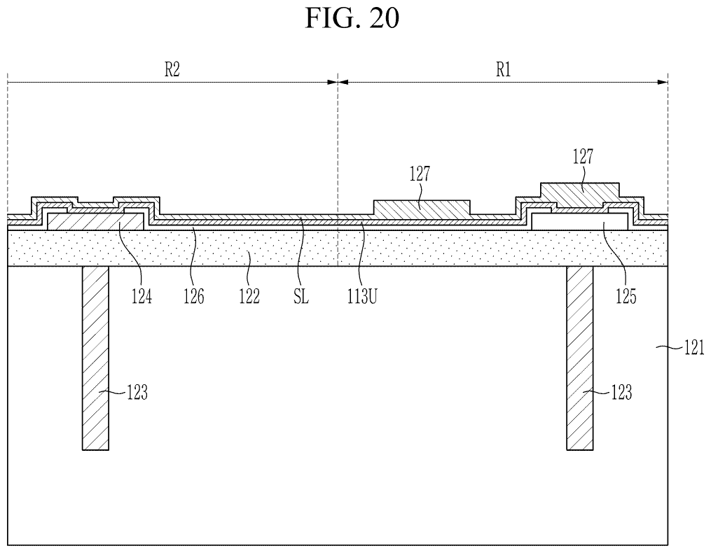

FIG. 20 is a cross-sectional view that illustrates removing the first photoresist pattern PRP1.

Referring to FIG. 20, the first photoresist pattern PRP1 may be removed. In an embodiment, the first photoresist pattern PRP1 may be removed by performing at least one of an etching process, an ashing process, and a strip process.

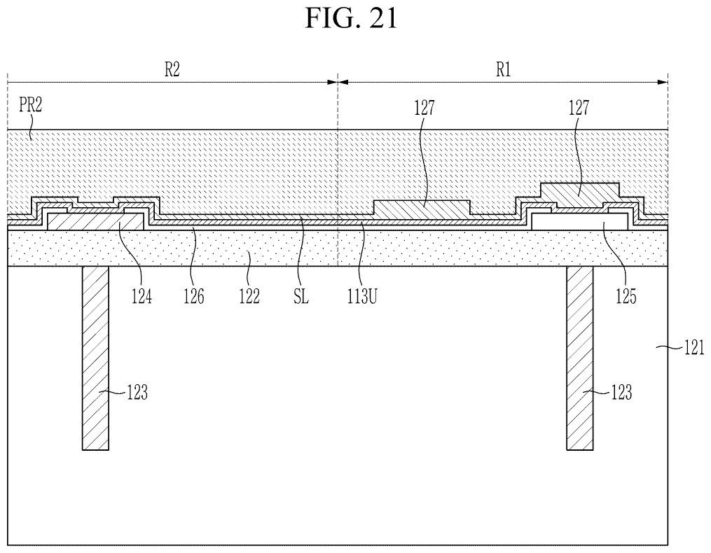

FIG. 21 is a cross-sectional view that illustrates forming a second photoresist PR2 on the seed metal layer SL and on the one or more dummy structures 127.

Referring to FIG. 21, the second photoresist PR2 may be applied on the seed metal layer SL and on the one or more dummy structures 127. In an embodiment, the second photoresist PR2 may be formed through a spin coating process. In an embodiment, the second photoresist PR2 may include an organic polymer resin including a photosensitivity material.

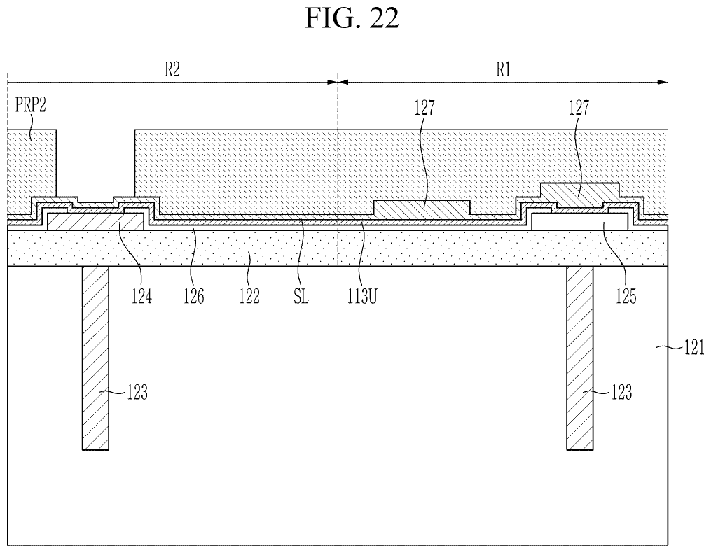

FIG. 22 is a cross-sectional view that illustrates forming a second photoresist pattern PRP2.

Referring to FIG. 22, by exposing and developing the second photoresist PR2, the second photoresist pattern PRP2 may be formed. The seed metal layer SL may be exposed through the second photoresist pattern PRP2.

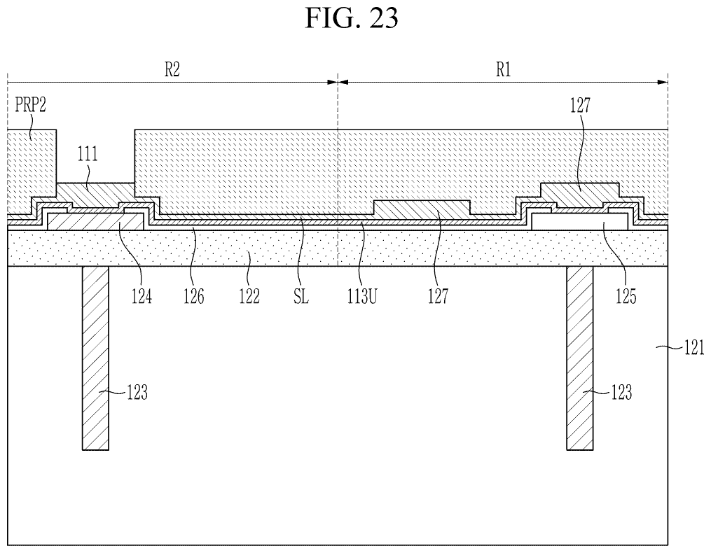

FIG. 23 is a cross-sectional view that illustrates forming bump pillars 111.

Referring to FIG. 23, by growing a metal layer through electrolytic plating from the seed metal layer SL that is already formed, the bump pillars 111 may be formed. The bump pillars 111 may be formed within the second region R2. Each of the bump pillars 111 may be formed on a corresponding conductive pad 124 of the conductive pads 124. The seed metal layer SL may not be distinguishable from the bump pillar 111. In an embodiment, the bump pillars 111 may be formed of a copper alloy including chromium, nickel, tin, gold, and a combination thereof, or copper. For example, the dummy patterns 127 and the bump pillar 111 may be formed of the same material.

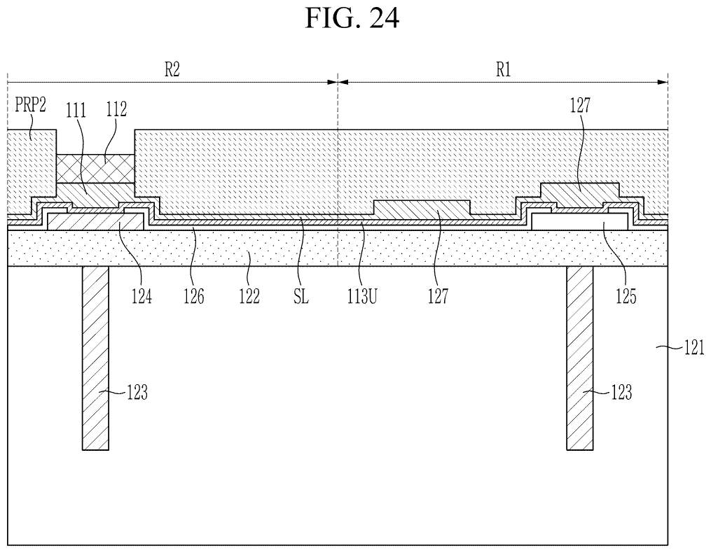

FIG. 24 is a cross-sectional view that illustrates forming solder balls 112.

Referring to FIG. 24, by growing a metal layer through electrolytic plating, the solder balls 112 may be formed. Each of the solder balls 112 may be formed on a corresponding bump pillar 111 of the bump pillars 111. In an embodiment, the solder balls 112 may include at least one of tin, silver, lead, nickel, copper and an alloy thereof

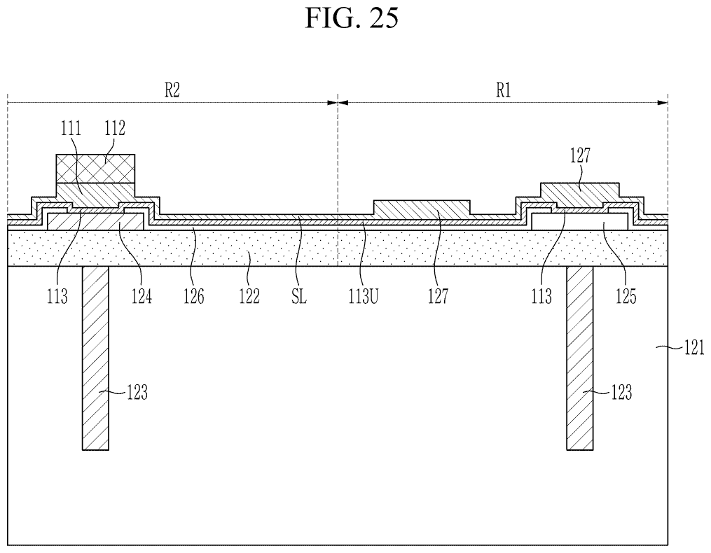

FIG. 25 is a cross-sectional view that illustrates removing the second photoresist pattern PRP2.

Referring to FIG. 25, the second photoresist pattern PRP2 may be removed. In an embodiment, the second photoresist pattern PRP2 may be removed by performing at least one of an etching process, an ashing process, and a strip process.

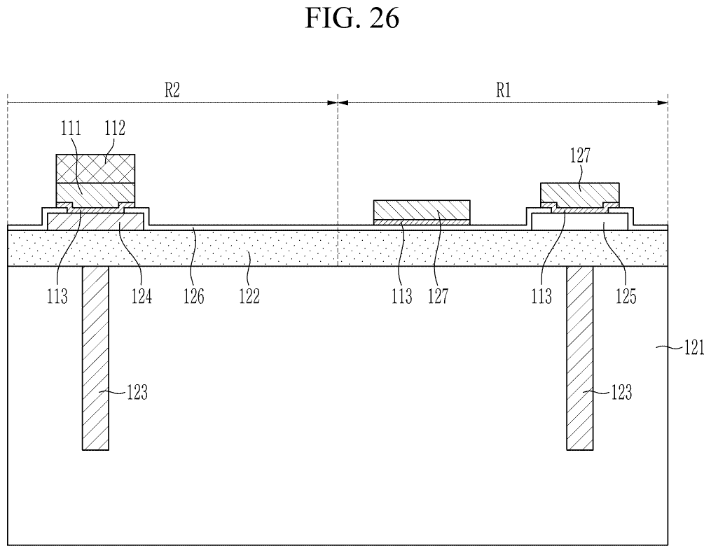

FIG. 26 is a cross-sectional view that illustrates removing the seed metal layer SL and the diffusion barrier wall layer 113U.

Referring to FIG. 26, the exposed seed metal layer SL and the diffusion barrier wall layer 113U may be removed. In an embodiment, the seed metal layer SL and the diffusion barrier wall layer 113U may be removed by an etching process.

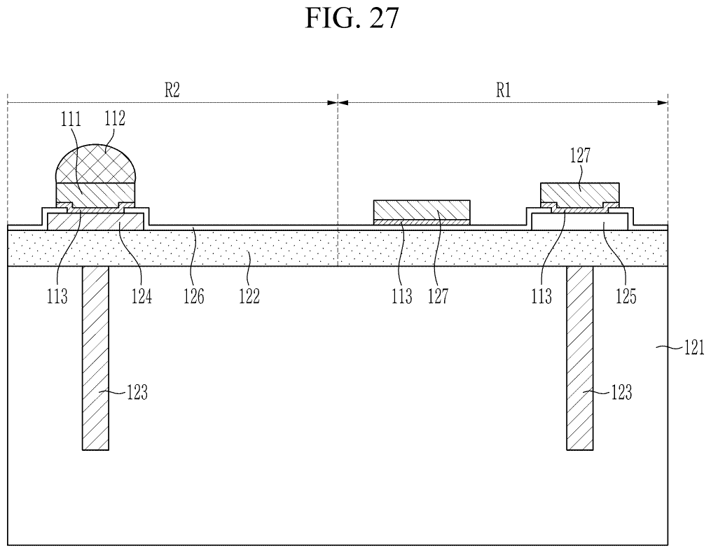

FIG. 27 is a cross-sectional view that illustrates reflowing the solder balls 112.

Referring to FIG. 27, by forming the solder balls 112 in a hemispherical shape by a reflow process, the solder ball 112 may be formed.

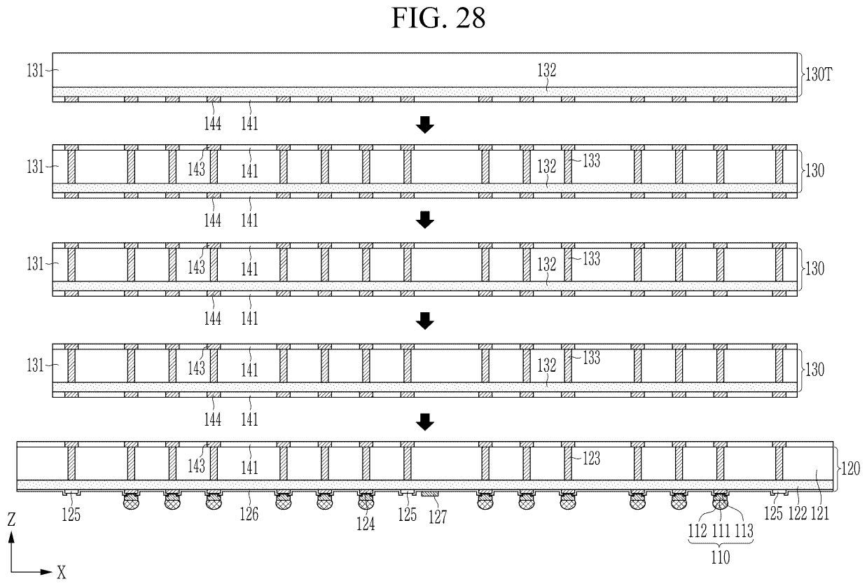

FIG. 28 to FIG. 31 are cross-sectional views for explaining a method of forming the high bandwidth memory (HBM) 100A of the embodiment of FIG. 4.

FIG. 28 is a cross-sectional view that illustrates stacking sequentially the memory dies 130 on the base die 120.

Referring to FIG. 28, by sequentially performing hybrid bonding processes, the memory dies 130 may be sequentially stacked on the base die 120. Hereinafter, the hybrid bonding process of the base die 120 and the memory die 130 will be described. The following description on the hybrid bonding process of the base die 120 and the memory die 130 may be equally applied to the hybrid bonding process during the process of sequentially stacking the memory dies 130.

Before the hybrid bonding, a chemical mechanical polishing (CMP) process may be performed. In an embodiment, a surface roughness of each of bonding surfaces where the hybrid bonding is performed may be about 10 Å or less. Then, the bonding surface of the back side insulating layer 141 of the base die 120 and the bonding surface of the front side insulating layer 142 of the memory die 130 may be activated. In an embodiment, the bonding surface of the back side insulating layer 141 and the bonding surface of the front side insulating layer 142 may be subject to surface processing by plasma activation. Then, a first base die 120 and the memory die 130 may be aligned for the hybrid bonding. Then, an activated bonding surface of the back side insulating layer 141 of the base die 120 and an activated bonding surface of the front side insulating layer 142 of the memory die 130 may contact to be pre-bonded.

Thereafter, the base die 120 and the memory die 130 may be hybrid bonded. First, the back side insulating layer 141 of the base die 120 and the front side insulating layer 142 of the memory die 130 may be bonded by the treatment. The treatment may strengthen bonding of the back side insulating layer 141 of the pre-bonded base die 120 and the front side insulating layer 142 of the memory die 130.

Then, each of the back side bonding pads 143 of the base die 120 and each of the front side bonding pads 144 of the memory die 130 may be bonded by annealing.

Subsequently, by performing the same hybrid process, the memory dies 130 may be sequentially stacked.

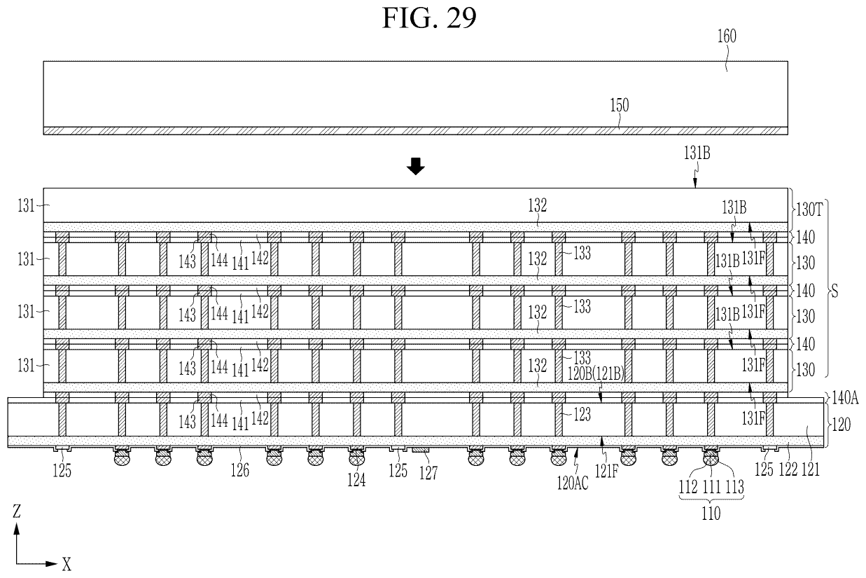

FIG. 29 is a cross-sectional view that illustrates attaching the dummy die 160 on the memory stack S.

Referring to FIG. 29, the dummy die 160 may be attached on the memory stack S. The dummy die 160 may be attached on the memory stack S by the adhesive member 150. In an embodiment, the adhesive member 150 may include the thermal interface material (TIM). In an embodiment, the adhesive member 150 may include thermal paste, a thermal pad, a phase change material (PCM), a metal material, or grease.

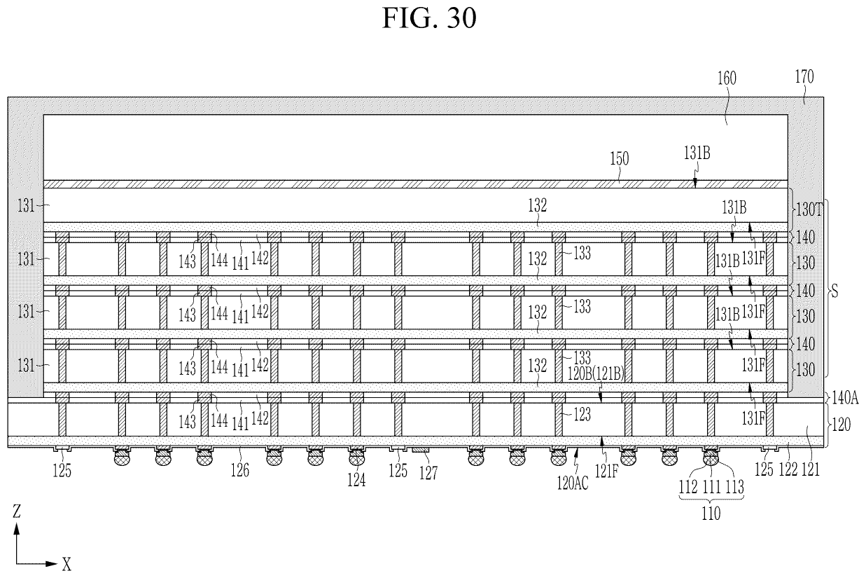

FIG. 30 is a cross-sectional view that illustrates molding the memory stack S, the adhesive member 150, and the dummy die 160, on the base die 120.

Referring to FIG. 30, the memory stack S, the adhesive member 150, and the dummy die 160 may be molded on the base die 120, by the molding material 170. As an embodiment, the process of molding by the molding material 170 may include a compression molding or transfer molding process. In an embodiment, the molding material 170 may include an epoxy molding compound (EMC).

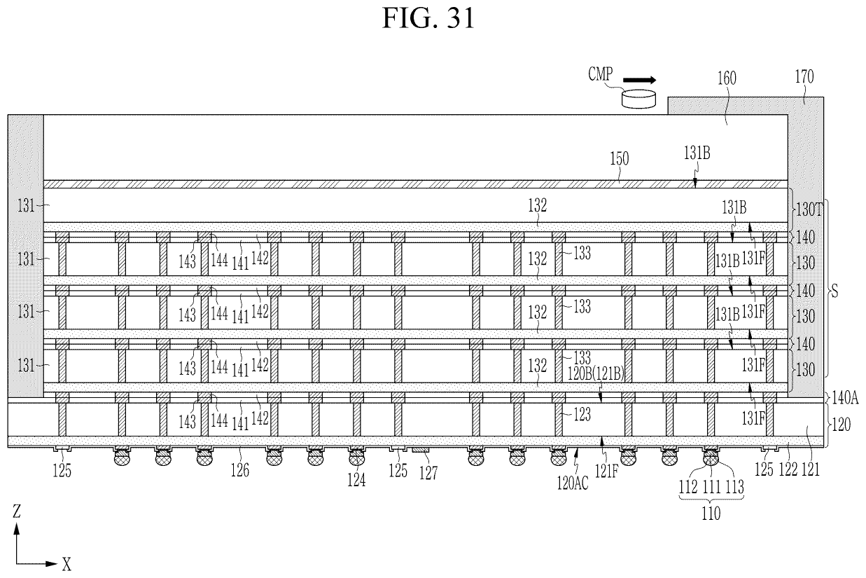

FIG. 31 is a cross-sectional view that illustrates performing a chemical mechanical polishing (CMP) process on the molding material 170.

Referring to FIG. 31, a chemical mechanical polishing (CMP) process may be performed to level the upper surface of the molding material 170. After performing the chemical mechanical polishing (CMP) process, the upper surface of the dummy die 160 may be exposed.

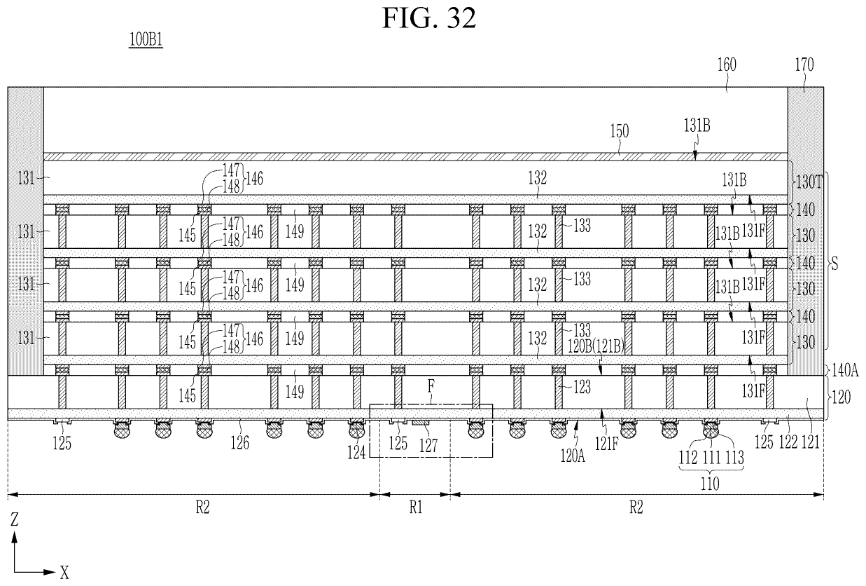

FIG. 32 is a cross-sectional view showing a high bandwidth memory (HBM) 100B1 of an embodiment. The content on the lower surface 120A of the base die 120 of the high bandwidth memory (HBM) 100A of the embodiment of FIG. 4 described with reference to FIG. 3 may also be applied to the high bandwidth memory (HBM) 100B1 of the embodiment of FIG. 32

Referring to FIG. 32, the first interconnection structure 140A may be disposed between the back side 121B of the die base 121 and the memory stack S. The second interconnection structures 140 may be alternately stacked with the memory dies 130. Each of the second interconnection structures 140 may be disposed between the back side 131B of the memory die base 131 of the memory die 130 and the front side structure 132 of a neighboring memory die 130. The first interconnection structure 140A and the second interconnection structures 140 each may include bonding pads 145, second bump structures 146, and an insulation member 149. As the second bump structures 146 are newly defined, the bump structures 110 may be referred to as a first bump structure 110.

Each of the bonding pads 145 of the first interconnection structure 140A may be disposed between a corresponding first through-substrate via (TSV) 123 of the first through-substrate vias (TSVs) 123 and a corresponding second bump structure 146 of the second bump structures 146. Each of the bonding pads 145 of the first interconnection structure 140A may directly electrically connect a corresponding first through-substrate via (TSV) 123 of the first through-substrate vias (TSVs) 123 to a corresponding second bump structure 146 of the second bump structures 146. Each of the bonding pads 145 of the second interconnection structure 140 may be disposed between a corresponding second through-substrate via (TSV) 133 of the second through-substrate vias (TSVs) 133 and a corresponding second bump structure 146 of the second bump structures 146. Each of the bonding pads 145 of the second interconnection structure 140 may directly electrically connect a corresponding second through-substrate via (TSV) 133 of the second through-substrate vias (TSVs) 133 to a corresponding second bump structure 146 of the second bump structures 146. In an embodiment, the bonding pads 145 may include at least one of copper, aluminum, tungsten, nickel, gold, tin, titanium and an alloy thereof.

The second bump structures 146 may be disposed between the base die 120 and the memory stack S, or between one memory die 130 and another memory die 130 neighboring thereto. Each of the second bump structures 146 may be disposed between a corresponding bonding pad 145 of the bonding pads 145 and a corresponding wire of wires of the front side structure 132 of the memory die 130. Each of the second bump structures 146 may include bump pillar 147 and solder ball 148. In an embodiment, the second bump structures 146 may include or be micro-bumps.

Each of the bump pillars 147 may be disposed between a corresponding solder ball 148 of the solder balls 148 and a corresponding wire of wires of the front side structure 132 of the memory die 130. Each of the bump pillars 147 may directly electrically connect a corresponding wire of wires of the front side structure 132 of the memory die 130 to a corresponding solder ball 148 of the solder balls 148. Each of the solder balls 148 may be disposed between a corresponding bonding pad 145 of the bonding pads 145 and a corresponding bump pillar 147 of the bump pillars 147. Each of the solder balls 148 may directly electrically connect a corresponding bump pillar 147 of the bump pillars 147 to a corresponding bonding pad 145 of the bonding pads 145. In an embodiment, bump pillar 147 may be formed of a copper alloy including silver, chromium, nickel, tin, gold, and a combination thereof, or copper. In an embodiment, the solder ball 148 may include at least one of tin, silver, lead, nickel, copper and an alloy thereof.

Each of insulation members 149 may be disposed between the base die 120 and the memory stack S, or between one memory die 130 and another memory die 130 neighboring thereto. Each of the insulation members 149 may surround and insulate the bonding pads 145 and the second bump structures 146. In an embodiment, the insulation members 149 may include a non-conductive film (NCF).

Regarding the content on the high bandwidth memory (HBM) 100B1 of FIG. 32 except for the above-described content, the content described in connection with the high bandwidth memory (HBM) 100A of FIG. 3 to FIG. 27 may be applied thereto.

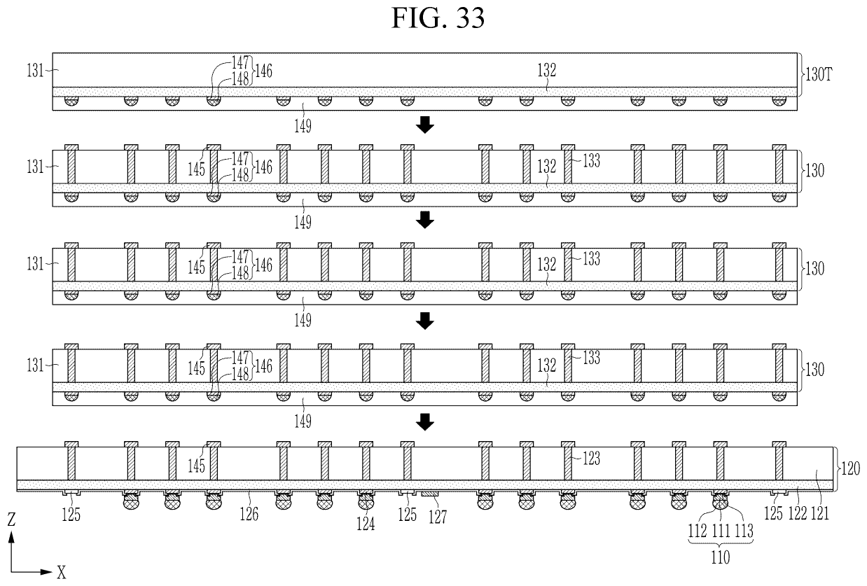

FIG. 33 to FIG. 36 are cross-sectional views for explaining a method of forming the high bandwidth memory (HBM) 100B1 of the embodiment of FIG. 32.

FIG. 33 is a cross-sectional view that illustrates stacking sequentially the memory dies 130 on the base die 120.

Referring to FIG. 33, each memory die 130 may be sequentially bonded on the base die 120 by a thermal compression (TC) process. The insulation member 149 may be attached on a lower surface of each memory die 130, and the second bump structures 146 on the lower surface of the memory die 130 may be surrounded by the insulation member 149.

By the thermal compression (TC) process, each of the second bump structures 146 may be bonded to a corresponding bonding pad 145 of the bonding pads 145. The insulation member 149 may be in a gel state before performing the thermal compression (TC) process, and the gel state may be changed to a liquid state as heat is applied while performing the thermal compression (TC) process, and finally changed to a cured state.

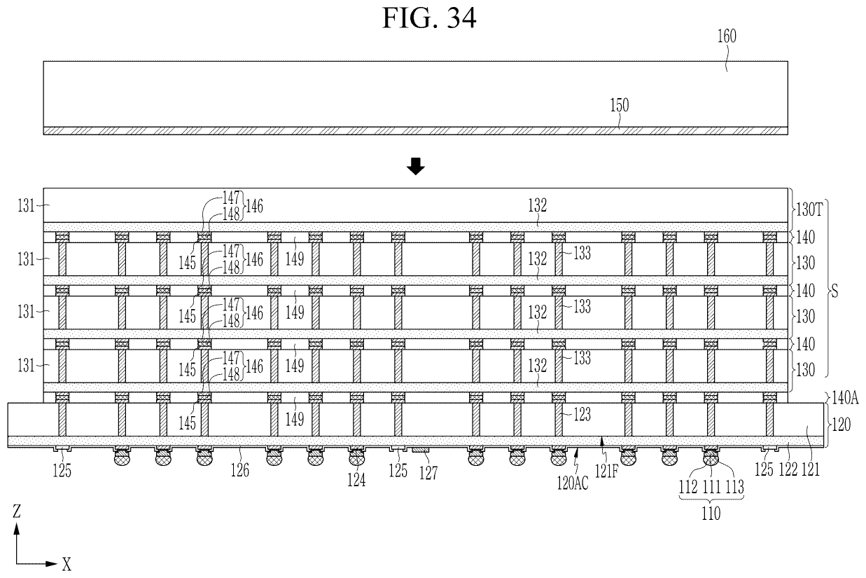

FIG. 34 is a cross-sectional view that illustrates attaching the dummy die 160 on the memory stack S.

Referring to FIG. 34, the dummy die 160 may be attached on the memory stack S. The dummy die 160 may be attached on the memory stack S by the adhesive member 150. In an embodiment, the adhesive member 150 may include the thermal interface material (TIM). In an embodiment, the adhesive member 150 may include thermal paste, a thermal pad, a phase change material (PCM), a metal material, or grease.

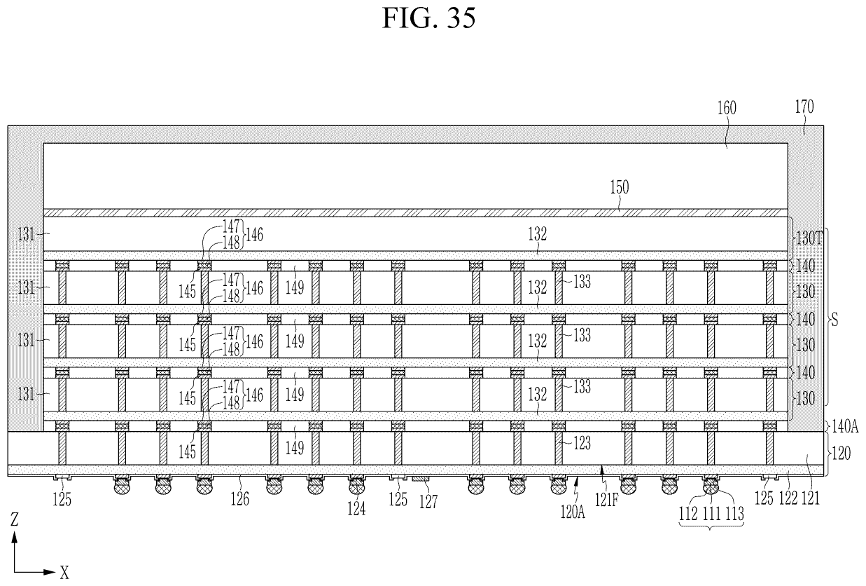

FIG. 35 is a cross-sectional view that illustrates molding the memory stack S, the adhesive member 150, and the dummy die 160, on the base die 120.

Referring to FIG. 35, the memory stack S, the adhesive member 150, and the dummy die 160 may be molded on the base die 120, by the molding material 170. As an embodiment, the process of molding by the molding material 170 may include a compression molding or transfer molding process. In an embodiment, the molding material 170 may include an epoxy molding compound (EMC).

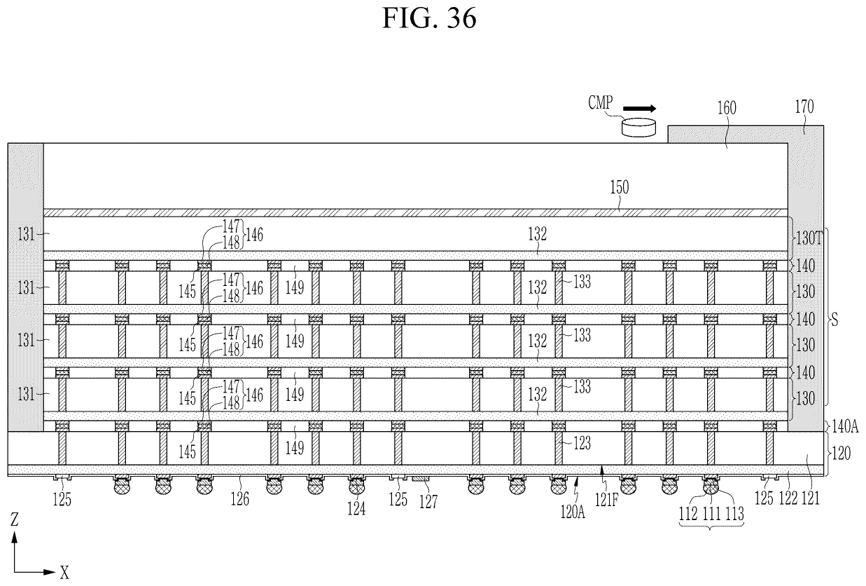

FIG. 36 is a cross-sectional view that illustrates performing a chemical mechanical polishing (CMP) process on the molding material 170.

Referring to FIG. 36, a chemical mechanical polishing (CMP) process may be performed to level the upper surface of the molding material 170. After performing the chemical mechanical polishing (CMP) process, the upper surface of the dummy die 160 may be exposed.

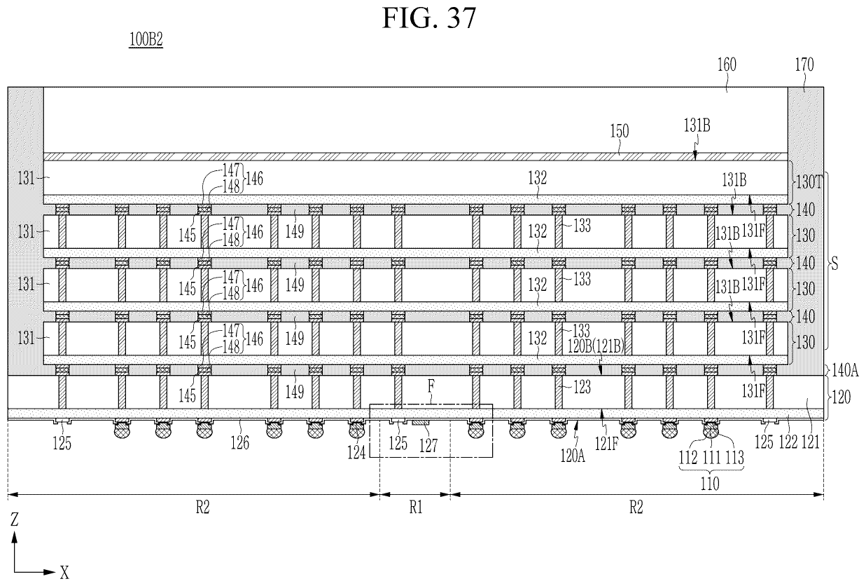

FIG. 37 is a cross-sectional view showing a high bandwidth memory (HBM) 100B2 of an embodiment. The content on the lower surface 120A of the base die 120 of the high bandwidth memory (HBM) 100A of the embodiment of FIG. 4 described with reference to FIG. 3 may also be applied to the high bandwidth memory (HBM) 100B2 of the embodiment of FIG. 37.

Referring to FIG. 37, the insulation members 149 may include a molded underfill (MUF). The insulation members 149 may include the same material as the molding material 170, and may be integrally formed with the molding material 170. In an embodiment, the insulation members 149 may include an epoxy molding compound (EMC).

Regarding the content on the high bandwidth memory (HBM) 100B2 of FIG. 7 except for the above-described content, the content described in connection with the high bandwidth memory (HBM) 100B1 of FIG. 32 may be applied thereto.

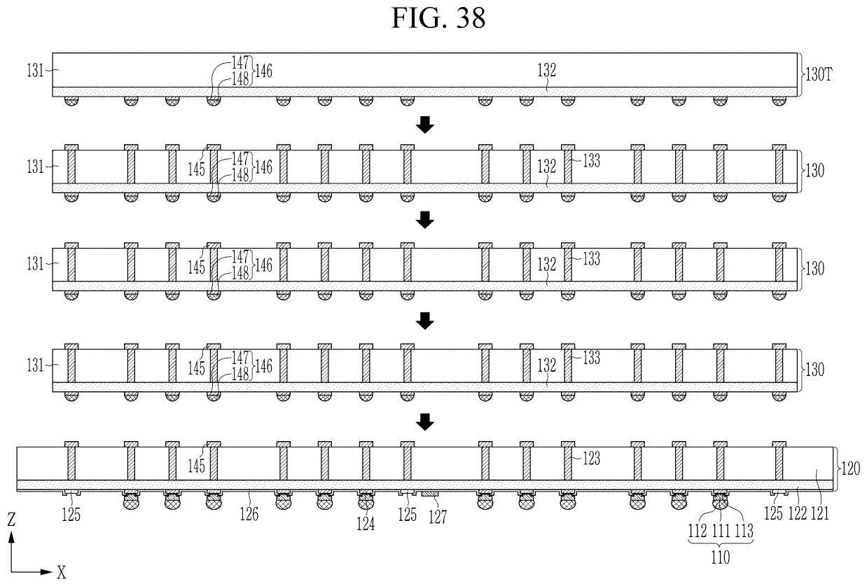

FIG. 38 to FIG. 41 are cross-sectional views for explaining a method of forming the high bandwidth memory (HBM) 100B2 of the embodiment of FIG. 37.

FIG. 38 is a cross-sectional view that illustrates stacking sequentially the memory dies 130 on the base die 120.

Referring to FIG. 38, each memory die 130 may be sequentially stacked on the base die 120 by a flip chip bonding process.

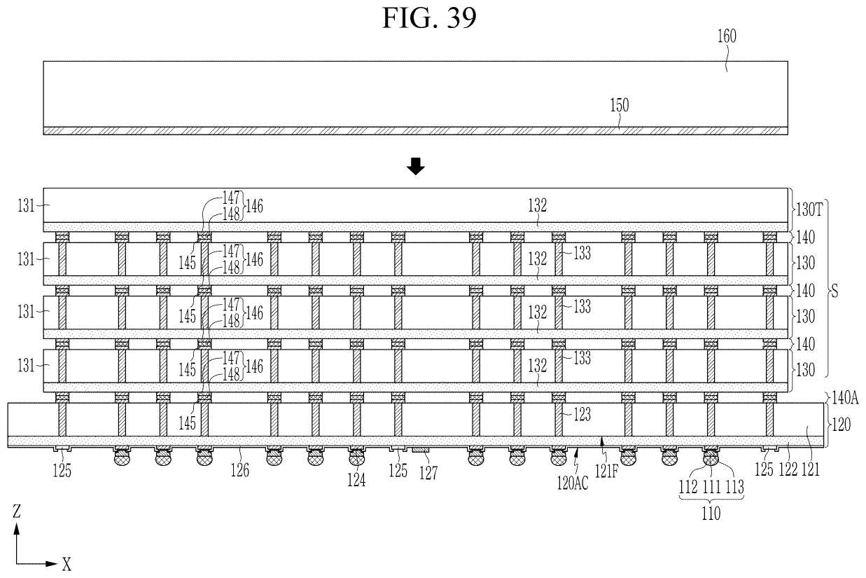

FIG. 39 is a cross-sectional view that illustrates attaching the dummy die 160 on the stacked memory dies 130.

Referring to FIG. 39, the dummy die 160 may be attached on the stacked memory dies 130. The dummy die 160 may be attached on the stacked memory dies 130 by the adhesive member 150. In an embodiment, the adhesive member 150 may include the thermal interface material (TIM). In an embodiment, the adhesive member 150 may include thermal paste, a thermal pad, a phase change material (PCM), a metal material, or grease.

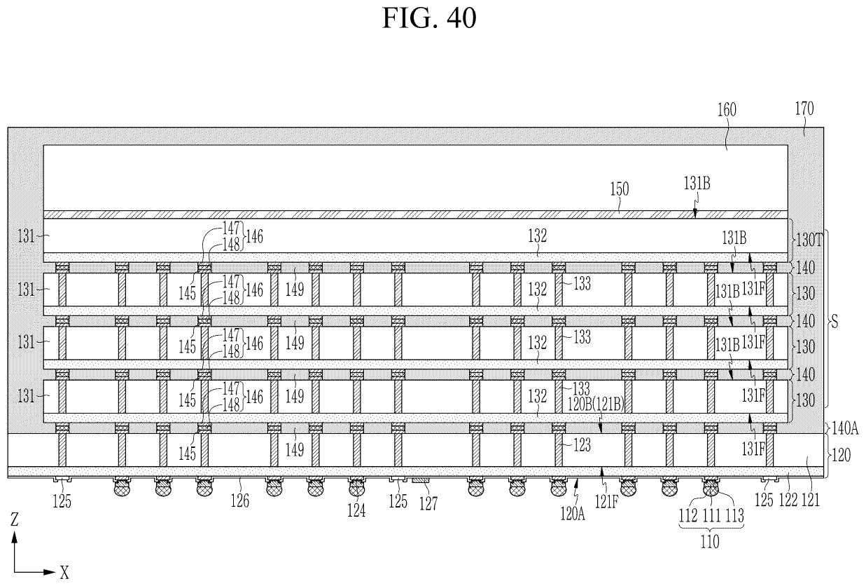

FIG. 40 is a cross-sectional view that illustrates molding the stacked memory dies 130, the adhesive member 150, and the dummy die 160, on the base die 120.

Referring to FIG. 40, the stacked memory dies 130, the adhesive member 150, and the dummy die 160 may be molded with the molding material 170, on the base die 120. While performing the molding process, the molding material 170 may function as the insulation member 149 at the same time, and may fill a space between the base die 120 and the memory die 130 neighboring to the base die 120, and between one memory die 130 and another memory die 130 neighboring thereto. The insulation member 149 may be the same material as the molding material 170. The insulation member 149 and the molding material 170 may become in a cured state after the molding process is completed. As an embodiment, the process of molding by the molding material 170 may include a compression molding or transfer molding process. In an embodiment, the molding material 170 may include an epoxy molding compound (EMC).

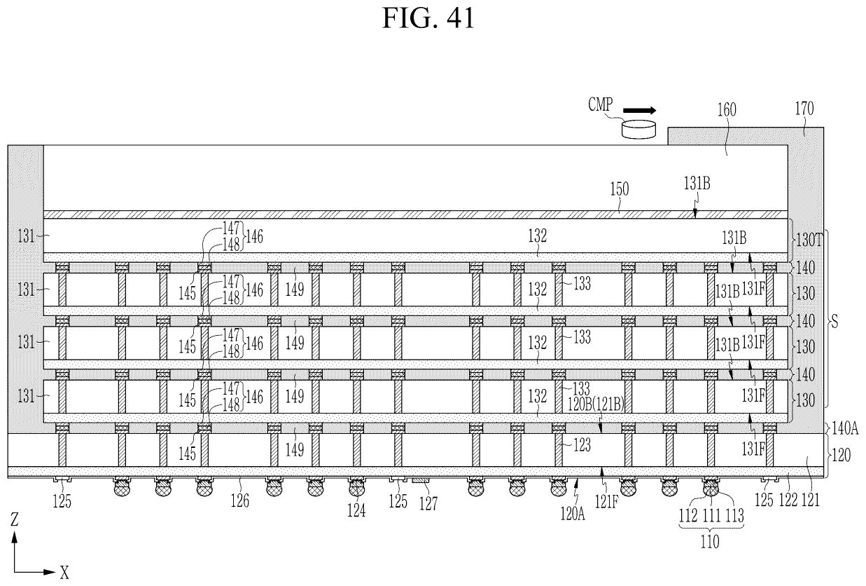

FIG. 41 is a cross-sectional view that illustrates performing a chemical mechanical polishing (CMP) process on the molding material 170.

Referring to FIG. 41, a chemical mechanical polishing (CMP) process may be performed to level the upper surface of the molding material 170. After performing the chemical mechanical polishing (CMP) process, the upper surface of the dummy die 160 may be exposed.

FIGS. 28 to 41 are illustrated such that dummy structures 127 are not formed on the test pads 125, it will be readily apparent to those skilled in the art that a method for manufacturing a HBM having dummy structures 127 formed on the test pads 125 (as shown in FIG. 27 and others) can be easily understood based on the detailed descriptions provided in FIGS. 28 to 41.

In some embodiments, before mounting the HBMs (described above) on a component (e.g., a first package substrate 1220 shown in FIG. 42), a test process may be performed using, e.g., a probe card. The test may induce a recess on the dummy structures 127 resulting from mechanical contact to a pin for the test.

In some embodiments, the dummy bumps 127 may be formed after the test process. For example, after the memory stack S and the base die 120 are connected to each other and before mounting the HBMs on the first package substrate 1220 which will be described with reference to FIG. 42, a test process may be performed using, e.g., a probe card. The test may induce a recess on the test pad 125 resulting from mechanical contact to a pin for the test. After the test process, the dummy bumps 127 may be formed on the pads 125, and the die bumps 110 may be formed on the pads 124.

FIG. 42 is a cross-sectional view illustrating an exemplary product that utilizes an interposer according to an embodiment.

Referring to FIG. 42, the electronic system 1000 may include an integrated package 1100 and a system substrate 1124. For example, the electronic system 1000 may be a graphics card. For example, the system substrate 1124 may be a mother board of the electronic system 1000.

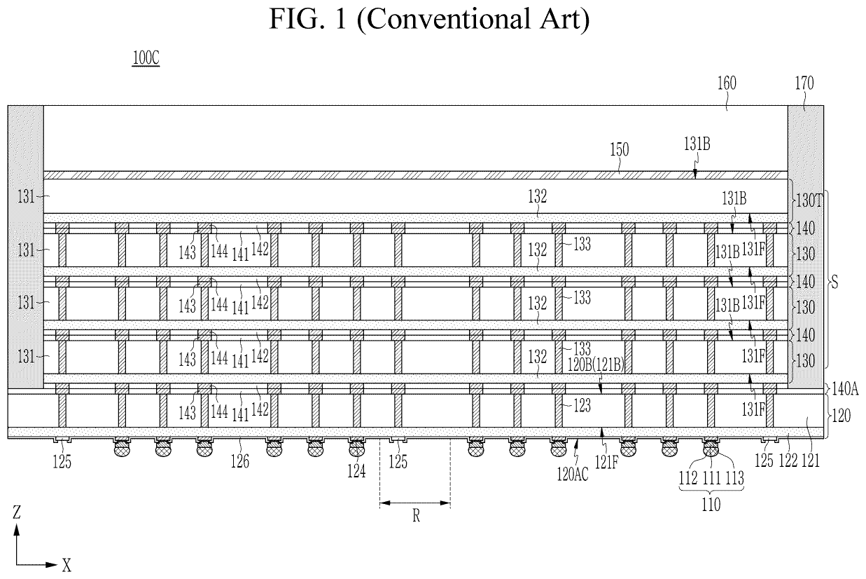

The integrated package 1100 may include a plurality of semiconductor devices 1001a and 1001b connected by using a first package substrate 1220 to a second package substrate 1222. The first package substrate 1220 may be an interposer. The first package substrate 1222 may include an upper surface having a plurality of first substrate pads. The second package substrate 1224 may include an upper surface having a plurality of second substrate pads. The integrated package 1100 may also have a mold layer (now shown in the drawing) covering the first package substrate 1220 and the plurality of semiconductor devices 1001a and 1001b. The first package substrate 1220 may include circuitry (not shown) for electrically connecting the plurality of semiconductor devices 1001a and 1001b to circuitry (not shown) of the second package substrate 1222. The plurality of semiconductor devices 1001a and 1001b may be electrically connected to each other by the first package substrate 1220. The plurality of semiconductor devices 1001a and 1001b may include a plurality of bump structures 110a. The plurality of bump structures 110a may provide an electrical connection between the circuitry of the first package substrate 1220 and the plurality of semiconductor devices 1001a and 1001b. The plurality of bump structures 110a may correspond to the bump structures 110 described with reference to FIGS. 1 to 41. Interposer bumps 110i may be utilized to provide an electrical connection between the circuitry of the first package substrate 1220 and the circuitry of the second package substrate 1222. The package substrate 1222 may be mounted and connected to the system substrate 1124, utilizing package terminals (e.g., solder balls) 110m. The second package substrate 1222 may be a base (or bottommost) substrate of the integrated package 1100 which includes the package terminals 110m.

The semiconductor device 1001a may be one of HBMs described with reference to FIGS. 1 to 41. The semiconductor device 1001b may be a host device such as a processor or a logic device (e.g., ASICs, FPGAs, GPUs, CPUs and so on). The HBM standard defines a physical interface for communication between the HBM and the host device. The circuitry of the first package substrate 1220 may connect circuitry of each of the semiconductor devices 1001a and 1001b to the second package substrate 1222 to enable communication of the semiconductor devices 1001a and 1001b with the system substrate 1124 after the integrated package 1100 is mounted. The bump structures 110a may connect circuitry of each of the semiconductor devices 1001a and 1001b to the first package substrate 1220 to enable communication with the second package substrate 1222 after the semiconductor devices 1001a and 1001b is mounted on the first package substrate 1220.

According to the embodiments, an electronic system may be provided. The system may include a substrate (e.g., first package substrate 1220, second package substrate 1222 or system substrate 1124) and a high bandwidth memory 1001a formed on the substrate. The high bandwidth memory may include a base die 120 and a memory stack S on the base die 120. The base die may include a first surface 120A and a second surface 120B facing away from the first surface 120A. A plurality of pads (124, 125 and 124D) may be provided on the first surface 120A. The plurality of pads may include a first set of pads 124 and a second set of pads 125. A plurality of conductive pillars (111 and 127) may be provided on the first surface 120A. The plurality of conductive pillars may include a first set of conductive pillars and a second set of conductive pillars.

Depending on the embodiments, in a plan view, a first group of conductive pillars (111 and 127) may overlap with a corresponding one of the plurality of pads (124, 125 and 124D), and a second group of conductive pillars (111 and 127) may not overlap with (be spaced apart from) the plurality of pads (124, 125 and 124D).

Depending on the embodiments, a third group of conductive pillars may be directly electrically connected to the substrate, and a fourth group of conductive pillars may be electrically isolated from the substrate.

Depending on the embodiments, a fifth group of conductive pillars may be directly electrically connected to the circuits formed in the base die, and a sixth group of conductive pillars may be electrically isolated from all of the circuits formed in the base die.

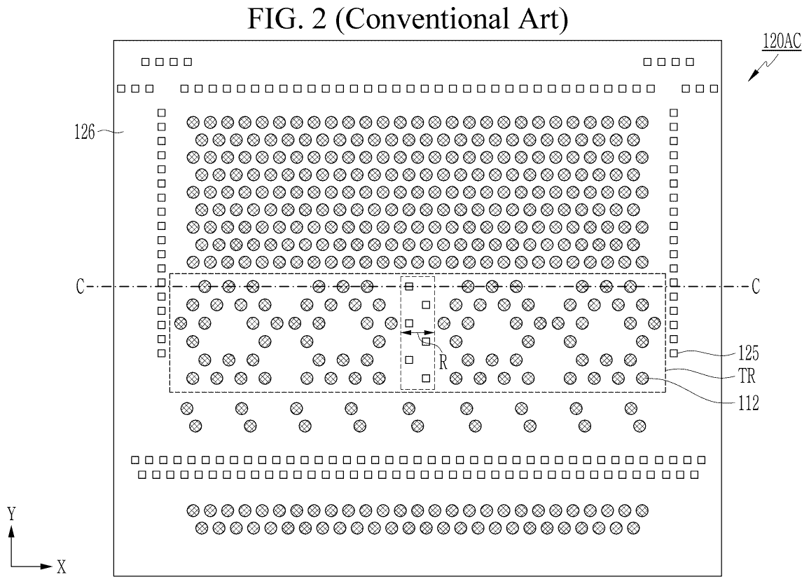

Referring back to FIGS. 1 and 2, when solder balls are not disposed in the region R, the metal density of the region R may be significantly lower than that of other regions, and therefore, the warpage value in the region R may be greater than that of other regions where solder balls 112 are disposed. The manufacturing of a semiconductor package is typically subject to a room temperature process or a high temperature process, and warpage may occur in the semiconductor package due to differences in coefficients of thermal expansion (CTE) between materials. The amount of warpage displacement in the region R where solder balls are not arranged is found to have a large value compared to other areas where solder balls 112 are arranged relatively uniformly. Accordingly, stress due to warpage is concentrated in the region R of the base die 120, and cracks may be generated on the surface of the region R where warpage appears the greatest. The crack may propagate from the surface of the region R to the wiring layer or the device layer of the base die 120, and the crack that has propagated to the wiring layer or the device layer of the base die 120 may affect integrated circuits or wirings, and may cause a problem of malfunctioning of the high bandwidth memory (HBM) 100C or deteriorating the reliability of the high bandwidth memory (HBM) 100C. In addition, as semiconductor chips become thinner due to the generational transition of semiconductor products, the frequency of cracks occurring in the base die 120 has increased, and as a result, the crack risk for high bandwidth memory (HBM) 100C has increased.

According to the embodiments described above, since the dummy patterns are disposed in the region R, the metal density of the region R may be substantially the same as or similar to that of other regions (e.g., where solder balls 112 are arranged relatively uniformly). Therefore, during the manufacturing process, warpage may be significantly reduced. Accordingly, the cracks due to warpage concentrated in the region R of the base die 120 may be suppressed, and the reliability of the high bandwidth memory may be enhanced.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A high bandwidth memory, comprising:
a base die comprising a first surface and a second surface that is opposite to the first surface, wherein the first surface comprises a first region and a second region around the first region;
one or more dummy patterns on the first region;
a plurality of bump patterns on the second region and next to the one or more dummy patterns; and
a semiconductor stack on the second surface of the base die, wherein the semiconductor stack comprises a plurality of core dies.

2. The high bandwidth memory of claim 1, wherein the one or more dummy patterns are electrically isolated from all circuits formed in the base die.

3. The high bandwidth memory of claim 1, wherein:
each of the plurality of bump patterns comprises:
a bump pillar; and
a solder ball on the bump pillar,
the base die further comprises a plurality of test pads formed in the first region, and
in a plan view, the plurality of test pads are spaced apart from the solder balls.

4. The high bandwidth memory of claim 1, wherein:
the one or more dummy patterns have a first thickness in a vertical direction;
the plurality of bump patterns have second thicknesses in the vertical direction; and
the first thickness is smaller than the second thicknesses.

5. The high bandwidth memory of claim 4, wherein each of the plurality of bump patterns comprises:
a bump pillar; and
a solder ball on the bump pillar,
wherein the bump pillar has a third thickness in the vertical direction, and
wherein the third thickness is equal to the first thickness, or greater than the first thickness.

6. The high bandwidth memory of claim 5, wherein the one or more dummy patterns is a dummy pillar.

7. The high bandwidth memory of claim 6, wherein the dummy patterns are electrically isolated from a device external to the high bandwidth memory.

8. The high bandwidth memory of claim 1, wherein each of the one or more dummy patterns has a circular shape, an elliptical shape, an elongated line shape, a rectangular shape, or a polygonal shape.

9. The high bandwidth memory of claim 1, wherein:
the one or more dummy patterns are a plurality of dummy patterns; and
the plurality of dummy patterns are consecutively arranged in one or more rows.

10. The high bandwidth memory of claim 1, wherein:
the one or more dummy patterns are a plurality of dummy patterns; and
the plurality of dummy patterns are disposed in a plurality of rows in a staggered manner.

11. A high bandwidth memory, comprising:
a buffer die comprising:
a die base comprising a first side and a second side that is opposite to the first side,
a device layer on the first side of the die base, and
a wiring layer on the device layer, the wiring layer comprising a plurality of test pads disposed in a first region of the wiring layer and a plurality of conductive pads disposed in a second region of the wiring layer that is positioned around the first region;
one or more dummy patterns on the first region;
a plurality of bump patterns on the second region, each of the plurality of bump patterns being disposed on a corresponding conductive pad of the plurality of conductive pads; and
a memory stack on the second side of the die base, wherein the memory stack comprises a plurality of memory dies.

12. The high bandwidth memory of claim 11, wherein:
the buffer die comprises a plurality of signal through-substrate vias and a plurality of power through-substrate vias; and
each of the plurality of test pads is directly electrically connected to a corresponding one of either the plurality of signal through-substrate vias or the plurality of power through-substrate vias.

13. The high bandwidth memory of claim 11, wherein the one or more dummy patterns do not overlap with the plurality of test pads in a vertical direction.

14. The high bandwidth memory of claim 11, wherein the one or more dummy patterns overlap with at least one test pad of the plurality of test pads in a vertical direction.

15. The high bandwidth memory of claim 11, wherein the one or more dummy patterns are electrically isolated from the plurality of test pads.

16. The high bandwidth memory of claim 11, wherein the plurality of test pads are electrical die sorting (EDS) test pads.

17. The high bandwidth memory of claim 11, wherein each of the plurality of test pads comprises a recess on a corresponding surface.

18. A high bandwidth memory, comprising:
a logic die comprising a first surface and a second surface that is opposite to the first surface, wherein the first surface comprises a first region and a second region around the first region;
one or more dummy patterns on the first region;
a plurality of first bump patterns on the second region and next to the one or more dummy patterns;
a memory stack on the second surface of the logic die, wherein the memory stack comprises a plurality of memory dies and a plurality of interconnection layers, and the plurality of memory dies and the plurality of interconnection layers are alternately stacked; and
a molding material covering the memory stack, on the second surface of the logic die.

19. The high bandwidth memory of claim 18, wherein each of the plurality of interconnection layers comprises:
a first insulating layer;
a second insulating layer disposed on the first insulating layer, and directly bonded to the first insulating layer;
a plurality of first bonding pads penetrating the first insulating layer; and
a plurality of second bonding pads penetrating the second insulating layer,
each of the plurality of first bonding pads is directly bonded to a corresponding second bonding pad of the plurality of second bonding pads.

20. The high bandwidth memory of claim 18, wherein each of the plurality of interconnection layers comprises:
second bump patterns each comprising a bump pillar and a solder ball; and
a non-conductive film surrounding the second bump patterns.
